(19) United States
(12) Patent Application Publication
(10) Pub. No.: US 2024/0333222 A1
(43) Pub. Date: Oct. 3, 2024

(54) HIGH FREQUENCY MODULE

(71) Applicant: Murata Manufacturing Co., Ltd., Nagaokakyo-shi (JP)

(72) Inventor: Naofumi TAKEZONO, Nagaokakyo-shi (JP)

(73) Assignee: Murata Manufacturing Co., Ltd., Nagaokakyo-shi (JP)

(21) Appl. No.: 18/616,230

(22) Filed: Mar. 26, 2024

(30) Foreign Application Priority Data
Mar. 30, 2023 (JP) 2023-055911

(51) Int. Cl. H03F 1/02; H03F 3/04; H03K 17/56

(52) U.S. Cl. CPC H03F 1/0233; H03F 3/04; H03K 17/56; H03F 2200/105

(57) ABSTRACT

A high frequency module includes: a first capacitor C1 having a first end connected to a first signal line; a second capacitor having a first end is connected to a second signal line; a first switch provided between a second end of the first capacitor and a reference potential; a second switch provided between a second end of the second capacitor and the reference potential; an inspection terminal allowing inspection of both the first switch and the second switch; and a resistor connected between a connection point between the first capacitor and the first switch.

### CROSS-REFERENCE TO RELATED APPLICATION

This application claims the benefit of priority to Japanese application no. 2023-055911, filed Mar. 30, 2023, the entire contents of which are hereby incorporated by reference.

### BACKGROUND OF THE DISCLOSURE

### 1. Field of the Disclosure

The present disclosure relates to a high frequency module.

### 2. Description of the Related Art

In recent years, the development of high frequency modules that integrate power amplifier circuits, switch circuits, control circuits, and the like has been progressing. In a high frequency module, a plurality of functional devices, such as a wafer level chip size package (WL-CSP) or surface mount device (SMD) are mounted on, for example, a low temperature co-fired ceramics (LTCC) board or a dielectric board. An LTCC is a type of multilayer ceramic substrate made by co-firing a mixture of glass and ceramic powders at a relatively low temperature.

As a technology to improve the efficiency of power amplifier circuits mounted on wireless communication terminals, there is an envelope tracking (ET) method that aims to improve power efficiency by controlling the power source voltage of an amplifier circuit according to an amplitude level of an input signal, or an average power tracking (APT) method that aims to improve power efficiency by controlling the power source voltage of an amplifier circuit according to average output power. Envelope tracking refers to a technique used to improve the efficiency of RF power amplifiers, in which voltage supplied to an amplifier is dynamically adjusted based on a signal's envelope to ensure the amplifier operates at optimal efficiency for each power level, reducing wasted power and heat generation. In the related art, a technology has been disclosed in which a capacitor that is grounded when supplying a variable supply voltage or a fixed supply voltage, is switched using a switch configured with an electric field effect transistor or the like (for example, Patent Document 1).

### SUMMARY OF THE DISCLOSURE

For example, it is assumed that an amplification integrated circuit (IC) configured with a heterojunction bipolar transistor (HBT) process and a control IC configured with (e.g., manufactured by) a silicon process, for example, are mounted on the same high frequency module. When inspecting such a high frequency module, although it is desirable to connect an inspection terminal of the high frequency module to a terminal of an inspection system in an attachable and detachable manner, the number of inspection terminals increases with the increase in the number of switch circuits, which may become an impediment to miniaturization or cost reduction.

The present disclosure has been made in view of the above, and an object of the present disclosure is to realize a high frequency module that can suppress the increase in the number of inspection terminals. That is, the high frequency module of the present disclosure reduces the number of inspection terminals needed.

A high frequency module according to one aspect of the present disclosure includes: a first capacitor having one end connected to a first signal line; a second capacitor having one end connected to a second signal line; a first switch that is provided between the other end of the first capacitor and a reference potential; a second switch that is provided between the other end of the second capacitor and the reference potential; an inspection terminal of the first switch and the second switch; and a resistor that is connected between a connection point between the first capacitor and the first switch and a connection point between the second capacitor and the second switch, in which the inspection terminal is electrically connected to one end of the resistor.

In this configuration, the first switch and the second switch can be inspected by using one inspection terminal without separately providing respective inspection terminals of the first switch corresponding to the first capacitor and the second switch corresponding to the second capacitor. Accordingly, it is possible to suppress the increase in the number of inspection terminals required in the pre-shipment inspection of the high frequency module.

A high frequency module according to another aspect of the present disclosure includes: a first capacitor having one end connected to a first signal line; a second capacitor having one end connected to a second signal line; a first switch that is provided between the other end of the first capacitor and a reference potential; a second switch that is provided between the other end of the second capacitor and the reference potential; an inspection terminal of the first switch and the second switch; and a first resistor and a second resistor that are connected in series between a connection point between the first capacitor and the first switch and a connection point between the second capacitor and the second switch, in which the inspection terminal is electrically connected to a connection point between the first resistor and the second resistor.

In this configuration, the first switch and the second switch can be inspected by using one inspection terminal without separately providing respective inspection terminals of the first switch corresponding to the first capacitor and the second switch corresponding to the second capacitor. Accordingly, it is possible to suppress the increase in the number of inspection terminals required in the pre-shipment inspection of the high frequency module.

According to the present disclosure, it is possible to realize a high frequency module that can suppress the increase in the number of inspection terminals.

Further scope of applicability of the invention will become apparent from the detailed description given hereinafter. However, it should be understood that the detailed description and specific examples, while indicating embodiments of the invention, are given by way of illustration only, since various changes and modifications within the scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a schematic diagram showing an example of a high frequency module.

FIG. 2 is an equivalent circuit diagram of an inspection terminal in pre-shipment inspection of the high frequency module.

FIG. 3 is a diagram showing an example of a switch determination in the pre-shipment inspection of the high frequency module.

FIG. 4 is a schematic diagram showing an example of a high frequency module according to Embodiment 1.

FIG. 5A is a Smith chart showing an example of a simulation result of impedance characteristics viewed from a power source terminal of the high frequency module according to Embodiment 1.

FIG. 5B is a Smith chart showing an example of a simulation result of the impedance characteristics viewed from the power source terminal of the high frequency module according to Embodiment 1.

FIG. 5C is a Smith chart showing an example of a simulation result of the impedance characteristics viewed from the power source terminal of the high frequency module according to Embodiment 1.

FIG. 6 is an equivalent circuit diagram of an inspection terminal in pre-shipment inspection of the high frequency module according to Embodiment 1.

FIG. 7A is a diagram showing an example of a switch determination in the pre-shipment inspection of the high frequency module according to Embodiment 1.

FIG. 7B is a diagram showing an example of a switch determination in the pre-shipment inspection of the high frequency module according to Embodiment 1.

FIG. 7C is a diagram showing an example of a switch determination in the pre-shipment inspection of the high frequency module according to Embodiment 1.

FIG. 7D is a diagram showing an example of a switch determination in the pre-shipment inspection of the high frequency module according to Embodiment 1.

FIG. 8 is a schematic diagram showing an example of a high frequency module according to Embodiment 2.

FIG. 9 is a schematic diagram showing an example of a high frequency module according to Embodiment 3.

FIG. 10 is an equivalent circuit diagram of an inspection terminal in pre-shipment inspection of the high frequency module according to Embodiment 3.

FIG. 11A is a diagram showing an example of a switch determination in the pre-shipment inspection of the high frequency module according to Embodiment 3.

FIG. 11B is a diagram showing an example of a switch determination in the pre-shipment inspection of the high frequency module according to Embodiment 3.

FIG. 11C is a diagram showing an example of a switch determination in the pre-shipment inspection of the high frequency module according to Embodiment 3.

FIG. 11D is a diagram showing an example of a switch determination in the pre-shipment inspection of the high frequency module according to Embodiment 3.

FIG. 12 is a schematic diagram showing an example of a high frequency module according to Embodiment 4.

FIG. 13 is a diagram showing an example of isolation characteristics between a power source voltage supply line and a high frequency signal transmission line of the high frequency module according to Embodiment 4.

FIG. 14 is an equivalent circuit diagram of an inspection terminal in pre-shipment inspection of the high frequency module according to Embodiment 4.

FIG. 15AA is a diagram showing an example of a switch determination in the pre-shipment inspection of the high frequency module according to Embodiment 4.

FIG. 15AB is a diagram showing an example of a switch determination in the pre-shipment inspection of the high frequency module according to Embodiment 4.

FIG. 15AC is a diagram showing an example of a switch determination in the pre-shipment inspection of the high frequency module according to Embodiment 4.

FIG. 15AD is a diagram showing an example of a switch determination in the pre-shipment inspection of the high frequency module according to Embodiment 4.

FIG. 15BA is a diagram showing an example of a switch determination in the pre-shipment inspection of the high frequency module according to Embodiment 4.

FIG. 15BB is a diagram showing an example of a switch determination in the pre-shipment inspection of the high frequency module according to Embodiment 4.

FIG. 15BC is a diagram showing an example of a switch determination in the pre-shipment inspection of the high frequency module according to Embodiment 4.

FIG. 15BD is a diagram showing an example of a switch determination in the pre-shipment inspection of the high frequency module according to Embodiment 4.

FIG. 15CA is a diagram showing an example of a switch determination in the pre-shipment inspection of the high frequency module according to Embodiment 4.

FIG. 15CB is a diagram showing an example of a switch determination in the pre-shipment inspection of the high frequency module according to Embodiment 4.

FIG. 15CC is a diagram showing an example of a switch determination in the pre-shipment inspection of the high frequency module according to Embodiment 4.

FIG. 15CD is a diagram showing an example of a switch determination in the pre-shipment inspection of the high frequency module according to Embodiment 4.

FIG. 15DA is a diagram showing an example of a switch determination in the pre-shipment inspection of the high frequency module according to Embodiment 4.

FIG. 15DB is a diagram showing an example of a switch determination in the pre-shipment inspection of the high frequency module according to Embodiment 4.

FIG. 15DC is a diagram showing an example of a switch determination in the pre-shipment inspection of the high frequency module according to Embodiment 4. and

FIG. 15DD is a diagram showing an example of a switch determination in the pre-shipment inspection of the high frequency module according to Embodiment 4.

### DESCRIPTION OF THE PREFERRED EMBODIMENTS

The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

Hereinafter, a high frequency module according to an embodiment will be described in detail based on the drawings. The present disclosure is not limited by the embodiment.

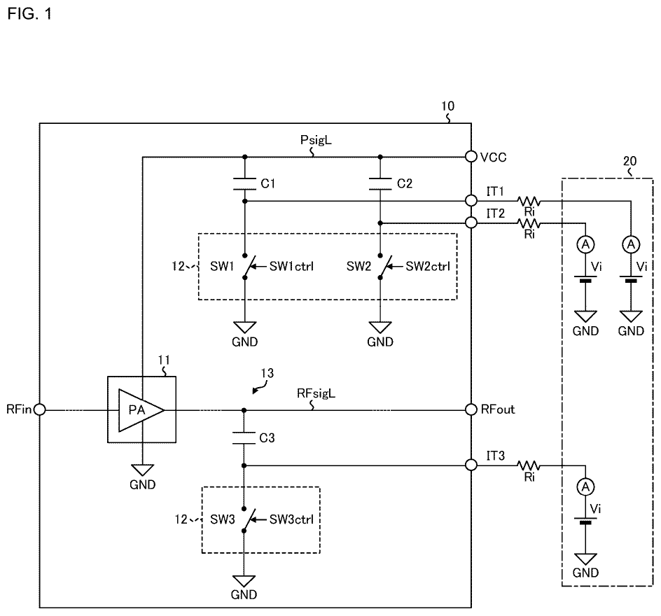

FIG. 1 is a schematic diagram showing an example of a high frequency module. In the present disclosure, a high frequency module 10 is an ultra-small integrated module on which a plurality of integrated circuits or various functional components are mounted. As the high frequency module 10, for example, a ceramic laminated board such as a low temperature co-fired ceramics (LTCC) board, a resin multi-layer board (or any known type of multi-layer boards), a film board, and the like are exemplified.

For example, a heterojunction bipolar transistor (HBT) device (e.g., integrated circuit, IC) composed of gallium arsenide (GaAs)-based heterojunction bipolar transistors (HBT), or for example, a silicon device (e.g., integrated circuit, IC) composed of silicon (Si)-based electric field effect transistors (FET) is mounted on the high frequency module 10. As the HBT device, for example, an amplifier circuit 11 is exemplified. As the silicon device, for example, a switch circuit 12, a control circuit that controls the switch circuit 12, or the like is an example.

In the example shown in FIG. 1, the amplifier circuit 11 is connected to a first signal line PsigL, which is a power source voltage supply line. The amplifier circuit 11 is supplied with a power source voltage from a power source terminal VCC of the high frequency module 10 with the first signal line PsigL interposed therebetween and amplifies a high frequency signal that is input from a high frequency signal input terminal RFin. In the present disclosure, the amplifier circuit 11 has an envelope tracking (ET) type power amplification mode (hereinafter, also referred to as a “first mode”) that aims to improve power efficiency by controlling the power source voltage according to an amplitude level of an input signal and an average power tracking (APT) type power amplification mode (hereinafter, also referred to as a “second mode”) that aims to improve power efficiency by controlling the power source voltage according to average output power.

In the first mode, power source voltage control for tracking an envelope line of the high frequency signal is performed. Therefore, in the first mode, a bypass capacitor having a relatively small capacitance with respect to that of the second mode is used. Specifically, a first mode bypass capacitor (e.g., a first capacitor C1) and a second mode bypass capacitor (e.g., a second capacitor C2) are configured to be switchable by the switch circuit 12. More specifically, as shown in FIG. 1, a first switch SW1 is provided which is controlled to be On and OFF through a control signal SW1ctrl, between the other end of the first mode bypass capacitor (e.g., the first capacitor C1) of which one end is connected to the first signal line PsigL and a reference potential GND. A second switch SW2 is provided which is controlled to be On and OFF through a control signal SW2ctrl, between the other end of the second mode bypass capacitor (e.g., the second capacitor C2) of which one end is connected to the first signal line PsigL and the reference potential GND. A capacitance value of the first mode bypass capacitor (e.g., the first capacitor C1) is, for example, set to 100 pF. A capacitance value of the second mode bypass capacitor (e.g., the second capacitor C2) is, for example, set to 0.1 μF.

The amplifier circuit 11 outputs the amplified high frequency signal to a high frequency signal output terminal RFout with the high frequency signal transmission line interposed therebetween. An output matching circuit 13 is provided on a second signal line RFsigL, which is a high frequency signal transmission line. Specifically, in the present disclosure, a capacitance value of a shunt capacitor (e.g., a third capacitor C3) composed of the output matching circuit 13 is configured to be switched through the switch circuit 12. More specifically, as shown in FIG. 1, a third switch SW3 is provided, which is controlled to be On and OFF through a control signal SW3ctrl, between the other end of the shunt capacitor (e.g., the third capacitor C3) of which one end is connected to the second signal line RFsigL and a reference potential GND. The control circuit (e.g., one or more of Application Specific Integrated Circuits (ASICS), Digital Signal Processors (DSPs), Digital Signal Processing Devices (DSPDs), Programmable Logic Devices (PLDs), Field Programmable Gate Arrays (FPGAs), processors, controllers, micro-controllers, microprocessors, other electronic units designed to produce the control signals SWctrl, SW1ctrl, SW2ctrl, SW3ctrl, and/or all of the control signals disclosed herein).

The first switch SW1, the second switch SW2, and the third switch SW3 are composed of, for example, a silicon type switching element such as an FET. The high frequency module 10 is provided with an inspection terminal of each switching element. In the configuration shown in FIG. 1, an inspection terminal IT1 for inspecting open circuit failures and short circuit failures of the first switch SW1, an inspection terminal IT2 for inspecting open circuit failures and short circuit failures of the second switch SW2, and an inspection terminal IT3 for inspecting open circuit failures and short circuit failures of the third switch SW3 are provided respectively.

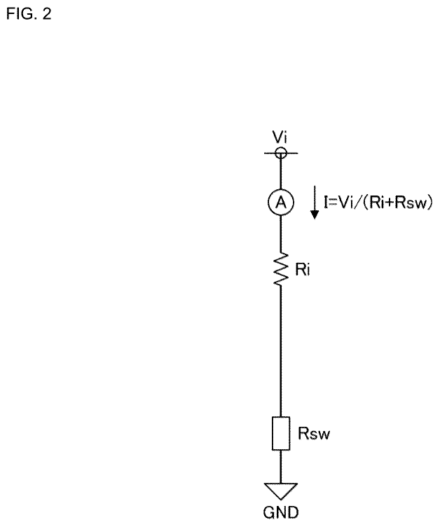

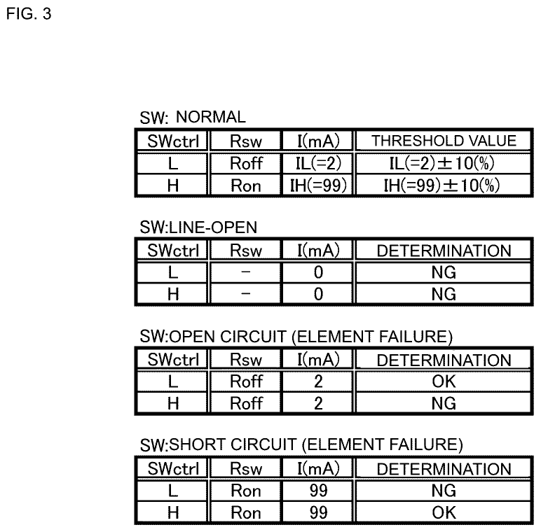

In the pre-shipment inspection of the high frequency module 10, each of the inspection terminals IT1, IT2, and IT3 is connected to an inspection system 20 with a current limit resistor Ri interposed therebetween, and a constant voltage Vi is supplied to each of the inspection terminals IT1, IT2, and IT3. FIG. 2 is an equivalent circuit diagram of the inspection terminal in pre-shipment inspection of the high frequency module. FIG. 3 is a diagram showing an example of a switch determination in the pre-shipment inspection of the high frequency module.

In FIG. 2, when resistance values of the first switch SW1, the second switch SW2, and the third switch SW3 (hereinafter, also simply referred to as a “switch SW”) are denoted by Rsw, a current I, which flows through the equivalent circuit shown in FIG. 2, is expressed by the following Equation (1).

$$I = Vi / ( Ri + Rsw ) \qquad ( 1 )$$

During when the switch SW is normal, the resistance value Rsw when the switch SW is controlled to be OFF (SW1ctrl, SW2ctrl, SW3ctrl (hereinafter, also simply referred to as a “SWctrl”)=“L”) can be represented as an OFF resistance Roff in the switching element. Further, the resistance value Rsw when the switch SW is controlled to be ON (SWctrl=“H”) can be represented as an ON resistance Ron in the switching element. Accordingly, as shown in FIG. 3, when the switch SW is normal, a current IL, which flows through the equivalent circuit shown in FIG. 2 when the switch SW is controlled to be OFF, and a current IH, which flows through the equivalent circuit shown in FIG. 2 when the switch SW is controlled to be ON, have different values from each other.

In the example shown in FIG. 3, an example is shown in which a determination is made that the switch SW is normal in a case where the current I when the switch SW is controlled to be OFF (SWctrl=“L”) is within a range of the current IL±10% when the switch SW is controlled to be OFF (SWctrl=“L”) during when the switch SW is normal, and in a case where the current I when the switch SW is controlled to be ON (SWctrl=“H”) is within a range of the current IH±10% when the switch SW is controlled to be ON (SWctrl=“H”) during when the switch SW is normal. In the “DETERMINATION” section of FIG. 3, “NG” refers to “not good” or “NOT-OK” or failure of the switch SW. Further, in the “DETERMINATION” section, “OK” refers to normal operation of the switch SW.

FIG. 3 shows an example of numerical values when a voltage value of the constant voltage Vi supplied from the inspection system 20 is set to 10 V, a resistance value of the current limit resistor Ri is set to 100 2, the OFF resistance Roff of the switching element is set to 5000 Q, and the ON resistance Ron of the switching element is set to 1 Q. Specifically, during when the switch SW is normal, it satisfies that the current IL=2 mA when the switch SW is controlled to be OFF (SWctrl=“L”), and the current IH=99 mA when the switch SW is controlled to be ON (SWctrl=“H”).

As one of the failure modes of the switch SW, on a connection path other than the switching element of the switch SW, for example, it is assumed that metal-to-metal contact defect due to bonding defect, or disconnection due to burnout or cracking caused by external factors, such as static electricity or physical factors, may occur. In this case, regardless of a control state of the switch SW, in other words, the resistance value Rsw of the switch SW becomes infinite regardless of whether the control signal SWctrl is “L” or “H”. In the present disclosure, a failure pattern in which the resistance value Rsw of the switch SW becomes infinite is defined as “line-open”. The current I at this time is substantially 0 and is determined to be NOT-OK regardless of the control state of the switch SW, as shown in FIG. 3.

When an open circuit failure occurs in the switching element of the switch SW, the resistance value Rsw of the switch SW becomes the OFF resistance Roff in the switching element regardless of the control state of the switch SW. At this time, the current I when the switch SW is controlled to be OFF (SWctrl=“L”) and the current I when the switch SW is controlled to be ON (SWctrl=“H”) are both 2 mA, and as shown in FIG. 3, the current I when the switch SW is controlled to be ON (SWctrl=“H”) is determined to be NOT-OK (e.g., “NG”).

When a short circuit failure occurs in the switching element of the switch SW, the resistance value Rsw of the switch SW becomes the ON resistance Ron in the switching element regardless of the control state of the switch SW. At this time, the current I when the switch SW is controlled to be OFF (SWctrl=“L”) and the current I when the switch SW is controlled to be ON (SWctrl=“H”) are both 99 mA, and as shown in FIG. 3, the current I when the switch SW is controlled to be OFF (SWctrl=“L”) is determined to be NOT-OK.

In the present disclosure, although an example is shown in which the current IL when the switch SW is controlled to be OFF and the current IH when the switch SW is controlled to be ON when the switch SW is normal are used as reference values and used as threshold values by respectively setting an upper limit value (IL+10%, IH+10%) and a lower limit value (IL−10%, IH−10%), the threshold value for failure determination of the switch SW is not limited to this. For example, an aspect may be used in which the threshold value is defined as an intermediate value (in the example shown in FIG. 3, a predetermined value between 2 mA or more and 99 mA or less) between the current IL when the switch SW is controlled to be OFF and the current IH when the switch SW is controlled to be ON when the switch SW is normal, and an aspect may be used in which the threshold value is set based on some kind of rule that may occur in the failure mode (e.g., line-open, open circuit failure and short circuit failure of the switching element) of the switch SW.

As described above, in the configuration shown in FIG. 1, inspection terminals ITn for inspecting open circuit failures and short circuit failures of switches SWn (n is an integer indicating the number of switches SW provided in the high frequency module 10) are respectively provided corresponding to the switches SWn. In such a configuration, the number of inspection terminals ITn increases as the number of switches SWn increases, which may become an impediment to miniaturization or cost reduction of the high frequency module 10. Hereinafter, a configuration of the high frequency module according to each embodiment that can suppress the increase in the number of inspection terminals will be described.

### Embodiment 1

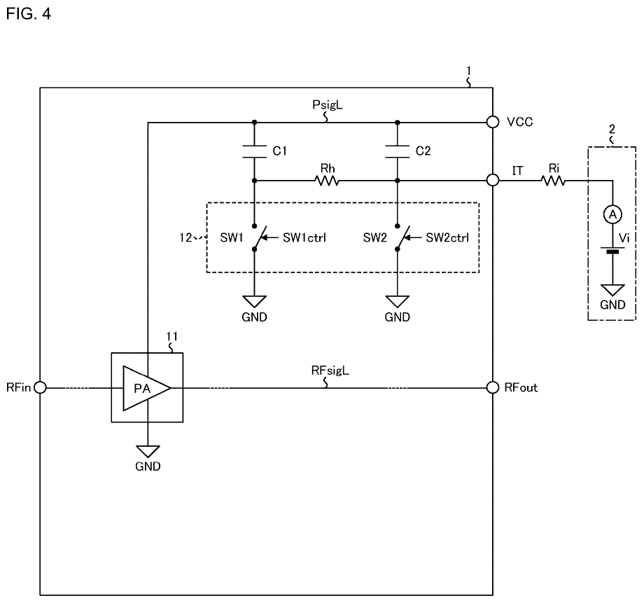

FIG. 4 is a schematic diagram showing an example of the high frequency module according to Embodiment 1. In the configuration shown in FIG. 4, in the high frequency module 1 according to Embodiment 1, a resistor Rh is connected between a connection point between the first mode bypass capacitor (e.g., the first capacitor C1) and the first switch SW1 and a connection point between the second mode bypass capacitor (e.g., the second capacitor C2) and the second switch SW2, and an inspection terminal IT is connected to one end (in FIG. 4, the connection point between the second mode bypass capacitor (e.g., the second capacitor C2) and the second switch SW2) of the resistor Rh.

The resistor Rh is a high impedance resistor having a relatively high resistance value with respect to the current limit resistor Ri. That is, the resistor RH can have a higher resistance value than a resistance value of the current limit resistor Ri. Specifically, the resistance value of the resistor Rh is, for example, set to 5000 Q. The current limit resistor Ri is connected between the inspection terminal IT and the inspection system 2.

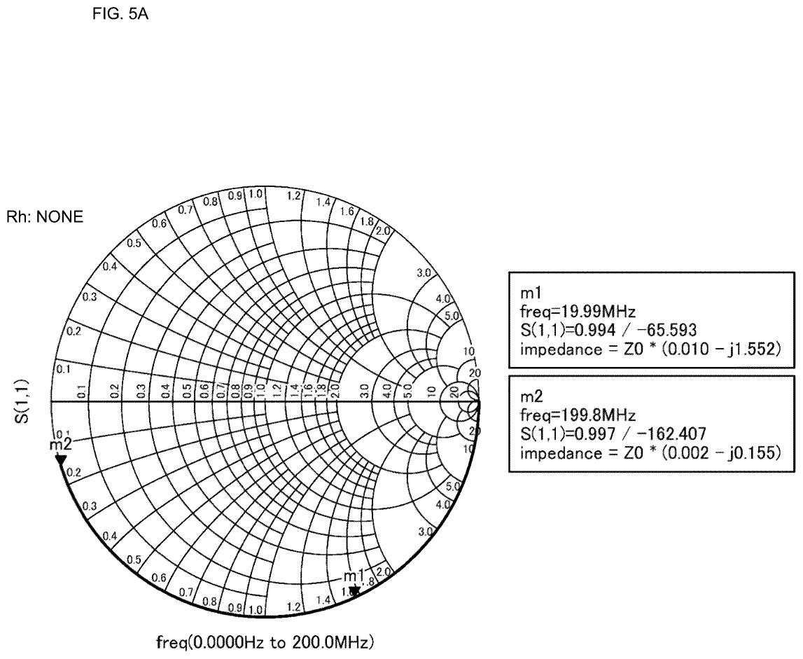

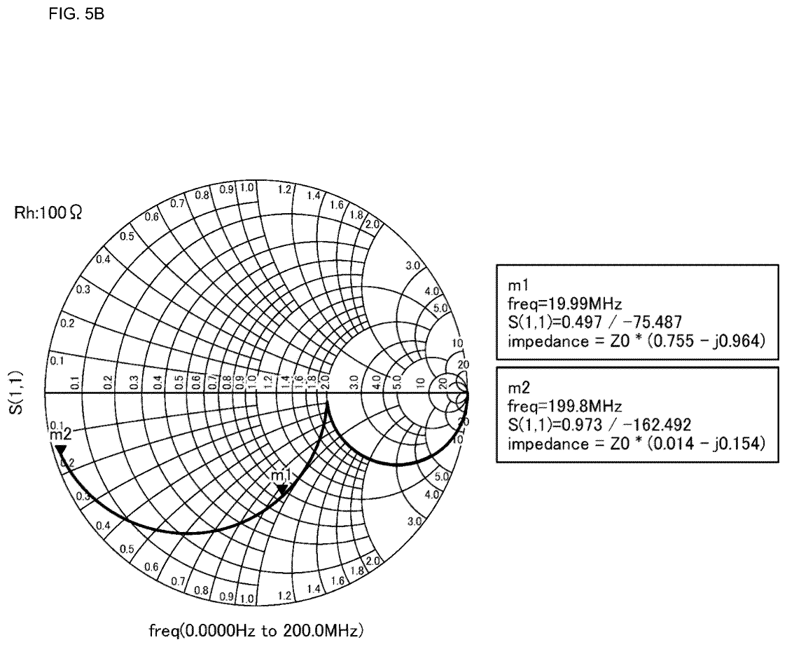

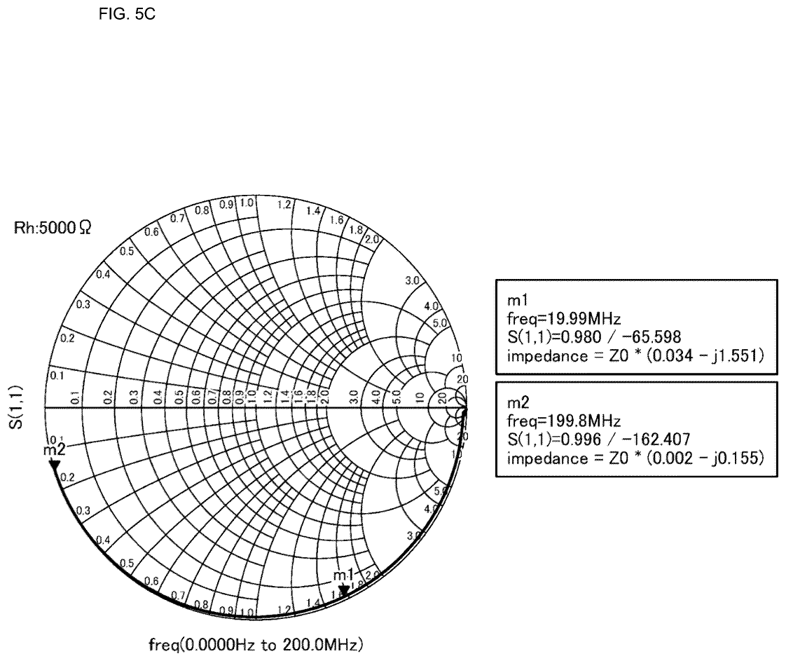

FIGS. 5A, 5B, and 5C are Smith charts showing an example of a simulation result of the impedance characteristics viewed from the power source terminal of the high frequency module according to Embodiment 1.

In FIGS. 5A, 5B, and 5C, an example is shown in which the first switch SW1 is controlled to be ON (SW1ctrl=“H”) and the second switch SW2 is controlled to be OFF (SW2ctrl=“L”) during when the first switch SW1 and the second switch SW2 are normal. FIG. 5A illustrates a simulation result when there is no resistor Rh. FIG. 5B illustrates a simulation result when the resistance value of the resistor Rh is set to 100Ω. FIG. 5C illustrates a simulation result when the resistance value of the resistor Rh is set to 5000Ω.

As shown in FIG. 5B, in the simulation result when the resistance value of the resistor Rh is set to 100Ω, the impedance decreases near 20 MHz corresponding to a modulation band width. In contrast, as shown in FIG. 5C, in the simulation result when the resistance value of the resistor Rh is set to 5000Ω, isolation substantially equivalent to the simulation result when there is no resistor Rh shown in FIG. 5A is ensured. Accordingly, deterioration in the isolation characteristics between switches can be suppressed.

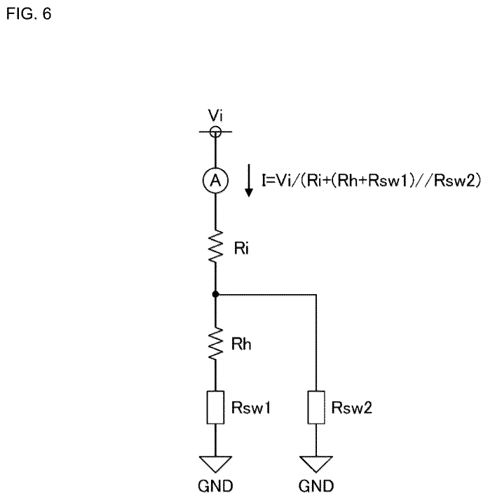

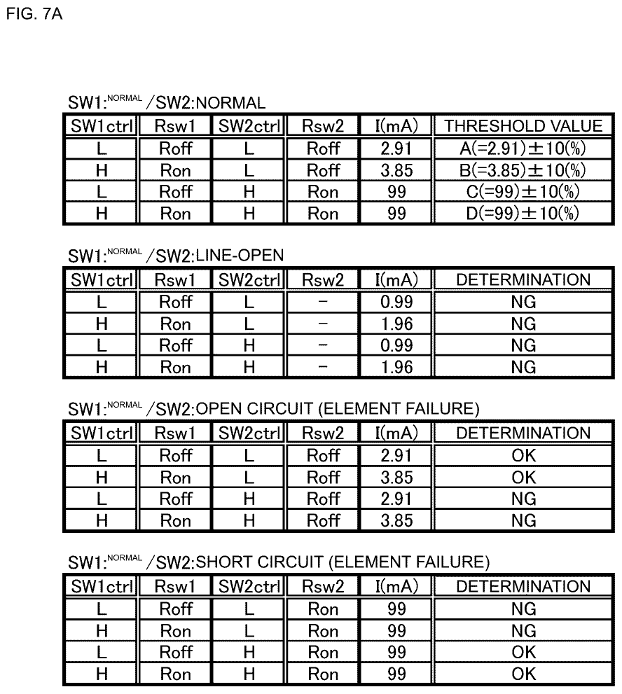

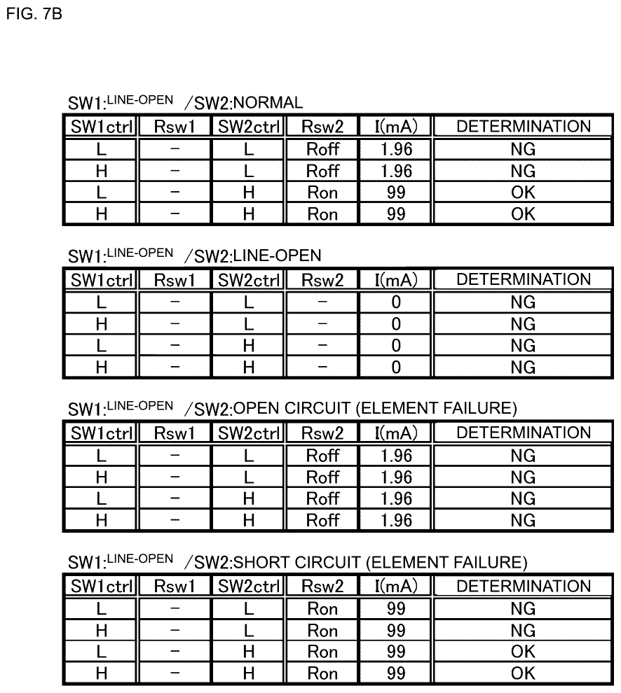

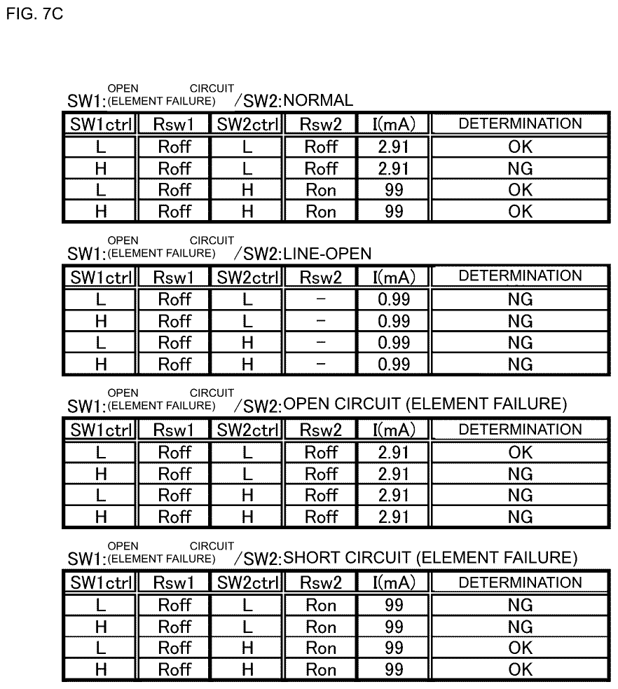

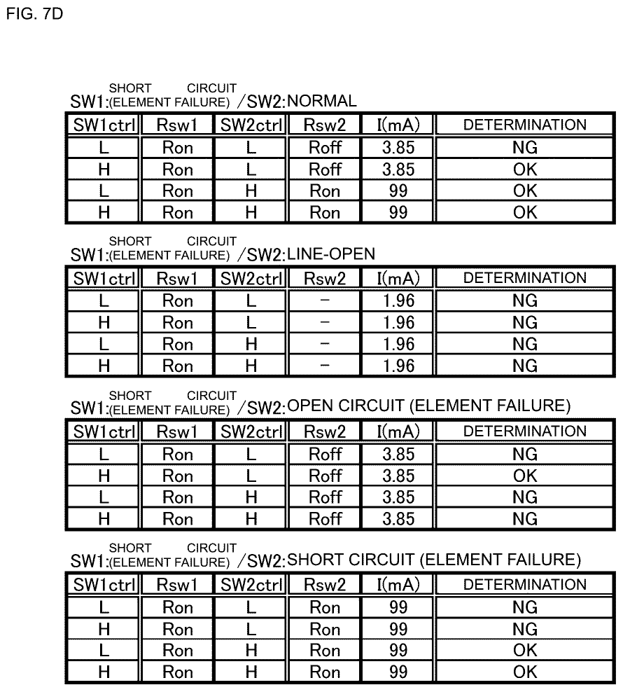

FIG. 6 is an equivalent circuit diagram of the inspection terminal in the pre-shipment inspection of the high frequency module according to Embodiment 1. FIGS. 7A, 7B, 7C, and 7D are diagrams showing an example of a switch determination in the pre-shipment inspection of the high frequency module according to Embodiment 1.

In FIG. 6, when the resistance value of the first switch SW1 is denoted by Rsw1 and the resistance value of the second switch SW2 is denoted by Rsw2, the current I flowing through the equivalent circuit shown in FIG. 6 is expressed by the following Equation (2).

$$I = Vi / ( Ri + ( Rh + Rsw 1 ) // Rsw 2 ) \qquad ( 2 )$$

During when the first switch SW1 and the second switch SW2 are normal, the resistance values Rsw1 and Rsw2 when the first switch SW1 and the second switch SW2 are controlled to be OFF (SW1ctrl, SW2ctrl=“L”) can be represented as an OFF resistance Roff in the switching element. Further, the resistance values Rsw1 and Rsw2 when the first switch SW1 and the second switch SW2 are controlled to be ON (SW1ctrl, SW2ctrl=“H”) can be represented as an ON resistance Ron in the switching element. Accordingly, when the first switch SW1 and the second switch SW2 are normal, as shown in FIG. 7A, the current I flowing through the equivalent circuit shown in FIG. 6 has different values depending on the control states of the first switch SW1 and the second switch SW2. Therefore, inspection of the first switch SW1 and the second switch SW2 can be performed by providing one inspection terminal IT without providing respective individual inspection terminals for the first switch SW1 corresponding to the first mode bypass capacitor (the first capacitor C1) and the second switch SW2 corresponding to the second mode bypass capacitor (the second capacitor C2).

In the examples shown in FIGS. 7A, 7B, 7C, and 7D, when the first switch SW1 and the second switch SW2 are normal, a range of the current I±10%, which flows through the equivalent circuit shown in FIG. 6 depending on the control states of the first switch SW1 and the second switch SW2, is defined as a threshold value range in each control state.

Specifically, in the examples shown in FIGS. 7A, 7B, 7C, and 7D, an example is shown in which a determination is made that the first switch SW1 and the second switch SW2 are normal when all of the respective following determination conditions are satisfied.

### Determination Condition 1

The current I when the first switch SW1 is controlled to be OFF (SW1ctrl=“L”) and when the second switch SW2 is controlled to be OFF (SW2ctrl=“L”) is within a range of a current A±10% when the first switch SW1 is controlled to be OFF (SW1ctrl=“L”) and when the second switch SW2 is controlled to be OFF (SW2ctrl=“L”) during when the first switch SW1 and the second switch SW2 are normal.

### Determination Condition 2

The current I when the first switch SW1 is controlled to be ON (SW1ctrl=“H”) and when the second switch SW2 is controlled to be OFF (SW2ctrl=“L”) is within a range of a current B±10% when the first switch SW1 is controlled to be ON (SW1ctrl=“H”) and when the second switch SW2 is controlled to be OFF (SW2ctrl=“L”) during when the first switch SW1 and the second switch SW2 are normal.

### Determination Condition 3

The current I when the first switch SW1 is controlled to be OFF (SW1ctrl=“L”) and when the second switch SW2 is controlled to be ON (SW2ctrl=“H”) is within a range of a current C±10% when the first switch SW1 is controlled to be OFF (SW1ctrl=“L”) and when the second switch SW2 is controlled to be ON (SW2ctrl=“H”) during when the first switch SW1 and the second switch SW2 are normal.

### Determination Condition 4

The current I when the first switch SW1 is controlled to be ON (SW1ctrl=“H”) and when the second switch SW2 is controlled to be ON (SW2ctrl=“H”) is within a range of a current D±10% when the first switch SW1 is controlled to be ON (SW1ctrl=“H”) and when the second switch SW2 is controlled to be ON (SW2ctrl=“H”) during when the first switch SW1 and the second switch SW2 are normal.

In other words, when at least any one of the above respective four determination conditions is not satisfied, at least one of the first switch SW1 and the second switch SW2 can be considered to be abnormal (e.g., failure).

Further, FIGS. 7A, 7B, 7C, and 7D show an example of numerical values when the constant voltage Vi, which is supplied from an inspection system 2, =10 V, the current limit resistor Ri=100Ω, the OFF resistance Roff of the switching element=5000Ω, and the ON resistance Ron of the switching element=1Ω.

Specifically, during when the first switch SW1 and the second switch SW2 are normal, the current A is 2.91 mA when the first switch SW1 is controlled to be OFF (SW1ctrl=“L”) and the second switch SW2 is controlled to be OFF (SW2ctrl=“L”).

Further, the current B is 3.85 mA when the first switch SW1 is controlled to be ON (SW1ctrl=“H”) and when the second switch SW2 is controlled to be OFF (SW2ctrl=“L”).

Further, the current C is 99 mA when the first switch SW1 is controlled to be OFF (SW1ctrl=“L”) and when the second switch SW2 is controlled to be ON (SW2ctrl=“H”).

Further, the current D is 99 mA when the first switch SW1 is controlled to be ON (SW1ctrl=“H”) and when the second switch SW2 is controlled to be ON (SW2ctrl=“H”).

When the failure mode of the second switch SW2 is line-open, the resistance value Rsw2 of the second switch SW2 becomes infinite regardless of the control state of the second switch SW2. At this time, the current I when the first switch SW1 is controlled to be OFF (SW1ctrl=“L”) is 0.99 mA, the current I when the first switch SW1 is controlled to be ON (SW1ctrl=“H”) is 1.96 mA, and as shown in FIG. 7A, the current I is determined to be NOT-OK regardless of the control states of the first switch SW1 and the second switch SW2.

When an open circuit failure occurs in the switching element of the second switch SW2, the resistance value Rsw2 of the second switch SW2 becomes the OFF resistance Roff in the switching element regardless of the control state of the second switch SW2. At this time, the current I when the first switch SW1 is controlled to be OFF (SW1ctrl=“L”) is 2.91 mA, the current I when the first switch SW1 is controlled to be ON (SW1ctrl=“H”) is 3.85 mA, and as shown in FIG. 7A, the current I when the second switch SW2 is controlled to be ON (SW2ctrl=“H”) is determined to be NOT-OK.

When a short circuit failure occurs in the switching element of the second switch SW2, the resistance value Rsw2 of the second switch SW2 becomes the ON resistance Ron in the switching element regardless of the control state of the second switch SW2. At this time, the current I when the first switch SW1 is controlled to be OFF (SW1ctrl=“L”) and the current I when the first switch SW1 is controlled to be ON (SW1ctrl=“H”) are both 99 mA, and as shown in FIG. 7A, the current I when the second switch SW2 is controlled to be OFF (SW2ctrl=“L”) is determined to be NOT-OK.

When the failure mode of the first switch SW1 is line-open, the resistance value Rsw1 of the first switch SW1 becomes infinite regardless of the control state of the first switch SW1. At this time, the current I when the second switch SW2 is controlled to be OFF (SW2ctrl=“L”) is 1.96 mA, the current I when the second switch SW2 is controlled to be ON (SW2ctrl=“H”) is 99 mA, and as shown in FIG. 7B, the current I when the second switch SW2 is controlled to be OFF (SW2ctrl=“L”) is determined to be NOT-OK.

When the failure modes of both the first switch SW1 and the second switch SW2 are line-open, the resistance values Rsw1 and Rsw2 of the first switch SW1 and the second switch SW2 become infinite regardless of the control states of the first switch SW1 and the second switch SW2. The current I at this time is substantially 0 regardless of the control states of the first switch SW1 and the second switch SW2, and as shown in FIG. 7B, the current I is determined to be NOT-OK regardless of the control states of the first switch SW1 and the second switch SW2.

When the failure mode of the first switch SW1 is line-open and an open circuit failure occurs in the switching element of the second switch SW2, the resistance value Rsw1 of the first switch SW1 becomes infinite regardless of the control state of the first switch SW1, and the resistance value Rsw2 of the second switch SW2 becomes the OFF resistance Roff in the switching element regardless of the control state of the second switch SW2. The current I at this time is 1.96 mA regardless of the control states of the first switch SW1 and the second switch SW2, and as shown in FIG. 7B, the current I is determined to be NOT-OK (e.g., “NG”) regardless of the control states of the first switch SW1 and the second switch SW2.

When the failure mode of the first switch SW1 is line-open and a short circuit failure occurs in the switching element of the second switch SW2, the resistance value Rsw1 of the first switch SW1 becomes infinite regardless of the control state of the first switch SW1, and the resistance value Rsw2 of the second switch SW2 becomes the ON resistance Ron in the switching element regardless of the control state of the second switch SW2. The current I at this time is 99 mA regardless of the control states of the first switch SW1 and the second switch SW2, and as shown in FIG. 7B, the current I when the second switch SW2 is controlled to be OFF (SW2ctrl=“L”) is determined to be NOT-OK.

When an open circuit failure occurs in the switching element of the first switch SW1, the resistance value Rsw1 of the first switch SW1 becomes the OFF resistance Roff in the switching element regardless of the control state of the first switch SW1. At this time, the current I when the second switch SW2 is controlled to be OFF (SW2ctrl=“L”) is 2.91 mA, the current I when the second switch SW2 is controlled to be ON (SW2ctrl=“H”) is 99 mA, and as shown in FIG. 7C, the first switch SW1 is controlled to be ON (SW1ctrl=“H”), and the current I in a state in which the second switch SW2 is controlled to be OFF (SW2ctrl=“L”) is determined to be NOT-OK.

When an open circuit failure occurs in the switching element of the first switch SW1 and the failure mode of the second switch SW2 is line-open, the resistance value Rsw1 of the first switch SW1 becomes the OFF resistance Roff in the switching element regardless of the control state of the first switch SW1, and the resistance value Rsw2 of the second switch SW2 becomes infinite regardless of the control state of the second switch SW2. The current I at this time is 0.99 mA regardless of the control states of the first switch SW1 and the second switch SW2, and as shown in FIG. 7C, the current I is determined to be NOT-OK regardless of the control states of the first switch SW1 and the second switch SW2.

When open circuit failures occur the switching elements of the first switch SW1 and the second switch SW2, the resistance value Rsw1 of the first switch SW1 and the resistance value Rsw2 of the second switch SW2 become the OFF resistance Roff in the switching elements regardless of the control states of the first switch SW1 and the second switch SW2. The current I at this time is 2.91 mA regardless of the control states of the first switch SW1 and the second switch SW2, and as shown in FIG. 7C, the current I is determined to be NOT-OK in a state in which the first switch SW1 is controlled to be ON (SW1ctrl=“H”) and the second switch SW2 is controlled to be OFF (SW2ctrl=“L”), and in a state in which the second switch SW2 is controlled to be ON (SW2ctrl=“H”) regardless of the control state of the first switch SW1.

When an open circuit failure occurs in the switching element of the first switch SW1 and a short circuit failure occurs in the switching element of the second switch SW2, the resistance value Rsw1 of the first switch SW1 becomes the OFF resistance Roff in the switching element regardless of the control state of the first switch SW1, and the resistance value Rsw2 of the second switch SW2 becomes the ON resistance Ron in the switching element regardless of the control state of the second switch SW2. The current I at this time is 99 mA regardless of the control states of the first switch SW1 and the second switch SW2, and as shown in FIG. 7C, the current I in a state in which the second switch SW2 is controlled to be OFF (SW2ctrl=“L”) is determined to be NOT-OK regardless of the control state of the first switch SW1.

When a short circuit failure occurs in the switching element of the first switch SW1, the resistance value Rsw1 of the first switch SW1 becomes the ON resistance Ron in the switching element regardless of the control state of the first switch SW1. At this time, the current I when the second switch SW2 is controlled to be OFF (SW2ctrl=“L”) is 3.85 mA, the current I when the second switch SW2 is controlled to be ON (SW2ctrl=“H”) is 99 mA, and as shown in FIG. 7D, the current I in a state in which both the first switch SW1 and the second switch SW2 are controlled to be OFF (SW1ctrl, SW2ctrl=“L”) is determined to be NOT-OK.

When a short circuit failure occurs in the switching element of the first switch SW1 and the failure mode of the second switch SW2 is line-open the resistance value Rsw1 of the first switch SW1 becomes the ON resistance Ron in the switching element regardless of the control state of the first switch SW1, and the resistance value Rsw2 of the second switch SW2 becomes infinite regardless of the control state of the second switch SW2. The current I at this time is 1.96 mA regardless of the control states of the first switch SW1 and the second switch SW2, and as shown in FIG. 7D, the current I is determined to be NOT-OK regardless of the control states of the first switch SW1 and the second switch SW2.

When a short circuit failure occurs in the switching element of the first switch SW1 and an open circuit failure occurs in the switching element of the second switch SW2, the resistance value Rsw1 of the first switch SW1 becomes the ON resistance Ron in the switching element regardless of the control state of the first switch SW1, and the resistance value Rsw2 of the second switch SW2 becomes the OFF resistance Roff in the switching element regardless of the control state of the second switch SW2. The current I at this time is 3.85 mA regardless of the control states of the first switch SW1 and the second switch SW2, and as shown in FIG. 7D, the current I is determined to be NOT-OK in a state in which both the first switch SW1 and the second switch SW2 are controlled to be OFF (SW1ctrl, SW2ctrl=“L”), and in a state in which the second switch SW2 is controlled to be ON (SW2ctrl=“H”) regardless of the control state of the first switch SW1.

When short circuit failures occur in the switching elements of the first switch SW1 and the second switch SW2, the resistance values Rsw1 and Rsw2 of the first switch SW1 and the second switch SW2 become the ON resistance Ron in the switching elements regardless of the control states of the first switch SW1 and the second switch SW2. The current I at this time is 99 mA regardless of the control states of the first switch SW1 and the second switch SW2, and as shown in FIG. 7D, the current I in a state in which the second switch SW2 is controlled to be OFF (SW2ctrl=“L”) is determined to be NOT-OK regardless of the control state of the first switch SW1.

As described above, in the high frequency module 1 according to Embodiment 1 having the configuration shown in FIG. 4, upper and lower limit values with respect to current values flowing through the equivalent circuit shown in FIG. 6 may be set as threshold values in each of the control states (“L”/“H” states of the control signals SW1ctrl and SW2ctrl, 22=4 ways) of the first switch SW1 and the second switch SW2 when the first switch SW1 and the second switch SW2 are normal, and a threshold value determination may be performed in each of the control states of the first switch SW1 and the second switch SW2 in the pre-shipment inspection of the high frequency module 1.

### Embodiment 2

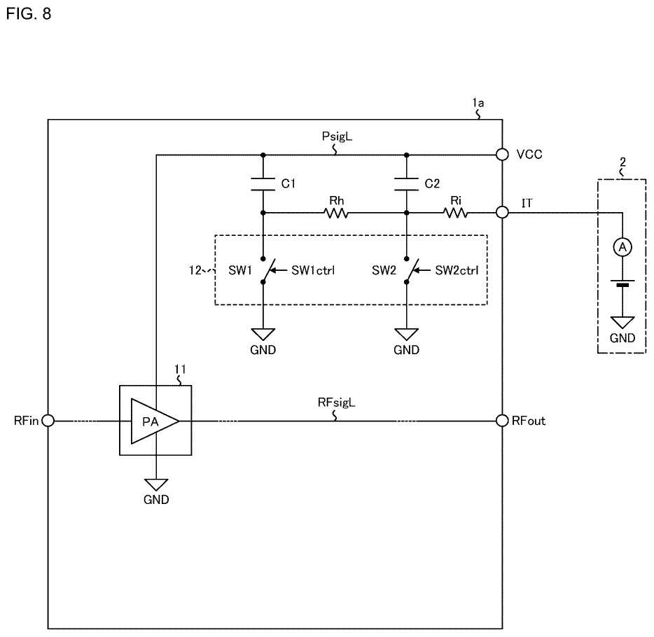

FIG. 8 is a schematic diagram showing an example of a high frequency module according to Embodiment 2. In the configuration shown in FIG. 8, in the high frequency module 1a according to Embodiment 2, the current limit resistor Ri is connected between one end (in FIG. 8, the connection point between the second mode bypass capacitor (the second capacitor C2) and the second switch SW2) of the resistor Rh and the inspection terminal IT. Accordingly, the electromagnetic wave noise of the high frequency signal component radiated from the inspection terminal IT to the outside of the high frequency module 1a can be suppressed.

### Embodiment 3

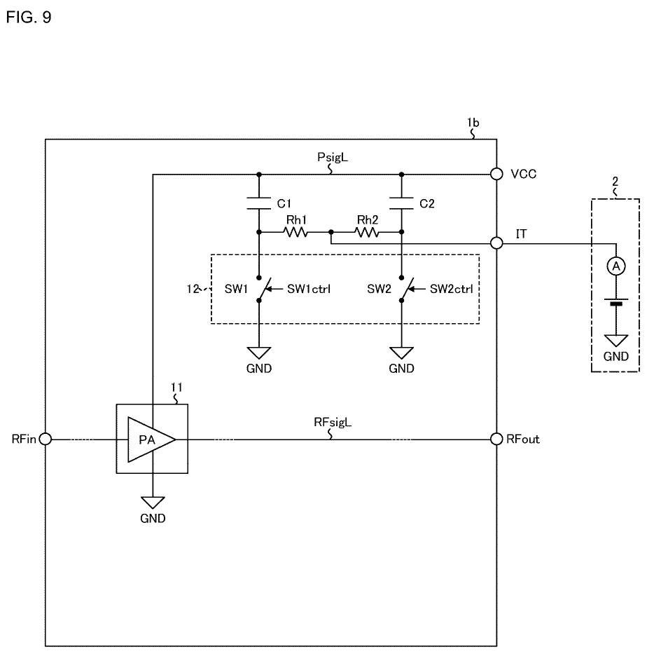

FIG. 9 is a schematic diagram showing an example of a high frequency module according to Embodiment 3. In the configuration shown in FIG. 9, in the high frequency module 1b according to Embodiment 3, a first resistor Rh1 and a second resistor Rh2 are connected in series between a connection point between the first mode bypass capacitor (the first capacitor C1) and the first switch SW1 and a connection point between the second mode bypass capacitor (the second capacitor C2) and the second switch SW2, and the inspection terminal IT is connected to a connection point between the first resistor Rh1 and the second resistor Rh2.

The first resistor Rh1 and the second resistor Rh2 are high impedance resistors having a relatively high resistance value with respect to the current limit resistor Ri. Specifically, the resistance values of the first resistor Rh1 and the second resistor Rh2 are, for example, set to 5000 In the configuration of the high frequency module 1b according to Embodiment 3 shown in FIG. 9, the current limit resistor Ri is not required. Further, similar to Embodiment 2, the electromagnetic wave noise of the high frequency signal component radiated from the inspection terminal IT to the outside of the high frequency module 1b can be suppressed. In addition to the configuration of the high frequency module 1b according to Embodiment 3 shown in FIG. 9, it is possible to employ a configuration including the current limit resistor Ri, similar to Embodiment 2.

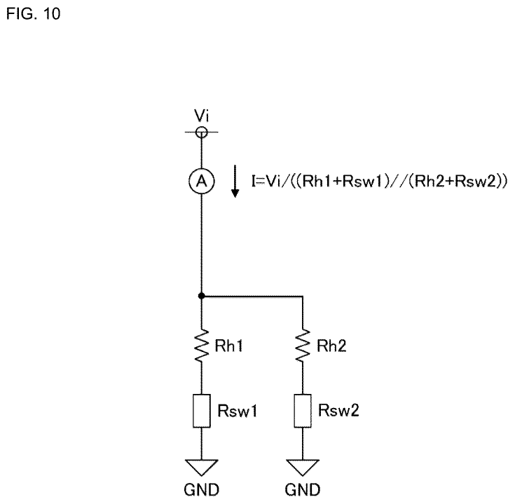

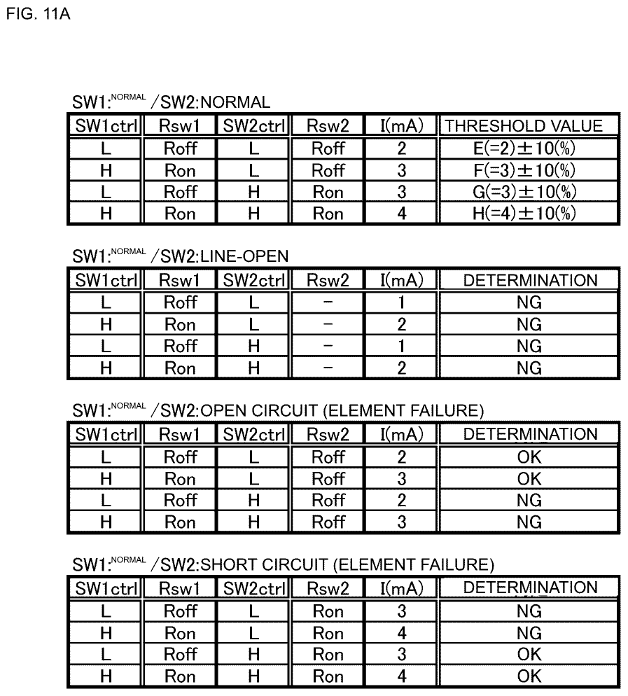

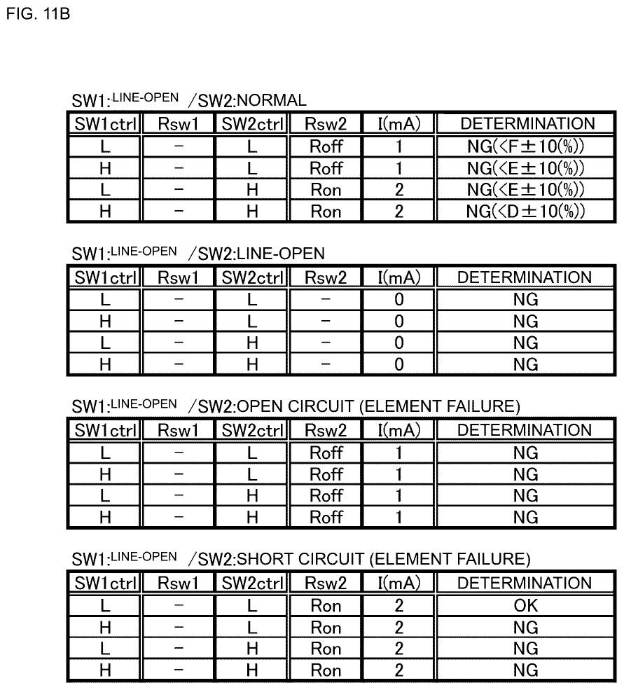

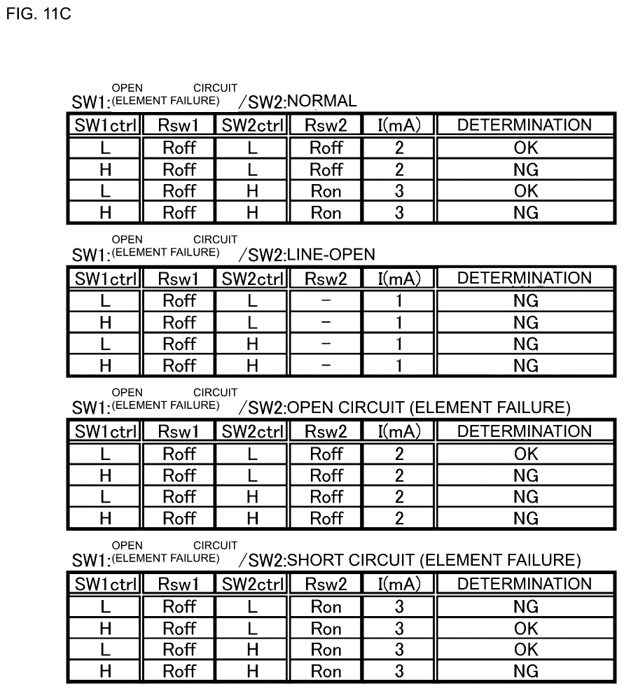

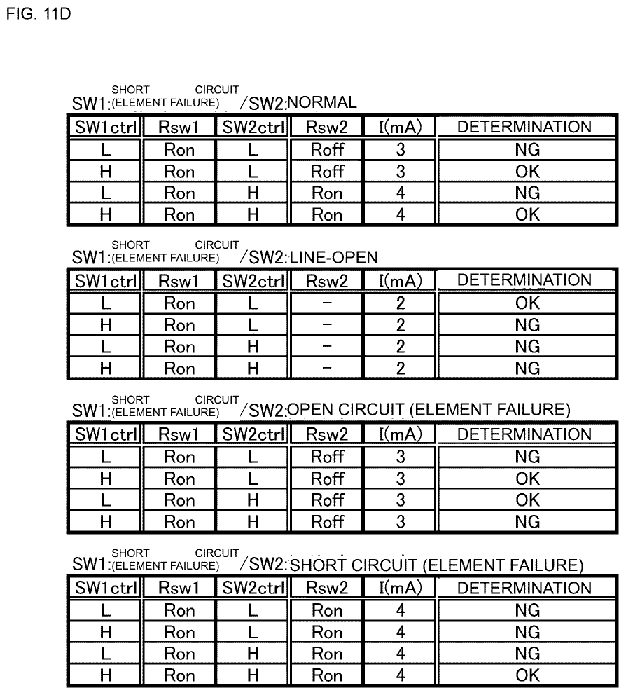

FIG. 10 is an equivalent circuit diagram of the inspection terminal in the pre-shipment inspection of the high frequency module according to Embodiment 3. FIGS. 11A, 11B, 11C, and 11D are diagrams showing an example of a switch determination in the pre-shipment inspection of the high frequency module according to Embodiment 3.

In FIG. 10, when the resistance value of the first switch SW1 is denoted by Rsw1 and the resistance value of the second switch SW2 is denoted by Rsw2, the current I flowing through the equivalent circuit shown in FIG. 10 is expressed by the following Equation (3).

$$I = Vi / ( ( Rh 1 + Rsw 1 ) // ( Rh 2 + Rsw 2 ) ) \qquad ( 3 )$$

During when the first switch SW1 and the second switch SW2 are normal, the resistance values Rsw1 and Rsw2 when the first switch SW1 and the second switch SW2 are controlled to be OFF (SW1ctrl, SW2ctrl=“L”) can be represented as an OFF resistance Roff in the switching element.

Further, the resistance values Rsw1 and Rsw2 when the first switch SW1 and the second switch SW2 are controlled to be ON (SW1ctrl, SW2ctrl=“H”) can be represented as an ON resistance Ron in the switching element. Accordingly, as shown in FIG. 11A, when the first switch SW1 and the second switch SW2 are normal, the current I flowing through the equivalent circuit shown in FIG. 10 has different values depending on the control states of the first switch SW1 and the second switch SW2.

In the examples shown in FIGS. 11A, 11B, 11C, and 11D, when the first switch SW1 and the second switch SW2 are normal, a range of the current I±10%, which flows through the equivalent circuit shown in FIG. 10 depending on the control states of the first switch SW1 and the second switch SW2, is defined as a threshold value range in each control state.

Specifically, in the examples shown in FIGS. 11A, 11B, 11C, and 11D, an example is shown in which a determination is made that the first switch SW1 and the second switch SW2 are normal when all of the respective following determination conditions are satisfied.

### Determination Condition 1

The current I when the first switch SW1 is controlled to be OFF (SW1ctrl=“L”) and when the second switch SW2 is controlled to be OFF (SW2ctrl=“L”) is within a range of a current E±10% when the first switch SW1 is controlled to be OFF (SW1ctrl=“L”) and when the second switch SW2 is controlled to be OFF (SW2ctrl=“L”) during when the first switch SW1 and the second switch SW2 are normal.

### Determination Condition 2

The current I when the first switch SW1 is controlled to be ON (SW1ctrl=“H”) and when the second switch SW2 is controlled to be OFF (SW2ctrl=“L”) is within a range of a current F±10% when the first switch SW1 is controlled to be ON (SW1ctrl=“H”) and when the second switch SW2 is controlled to be OFF (SW2ctrl=“L”) during when the first switch SW1 and the second switch SW2 are normal.

### Determination Condition 3

The current I when the first switch SW1 is controlled to be OFF (SW1ctrl=“L”) and when the second switch SW2 is controlled to be ON (SW2ctrl=“H”) is within a range of a current G±10% when the first switch SW1 is controlled to be OFF (SW1ctrl=“L”) and when the second switch SW2 is controlled to be ON (SW2ctrl=“H”) during when the first switch SW1 and the second switch SW2 are normal.

### Determination Condition 4

The current I when the first switch SW1 is controlled to be ON (SW1ctrl=“H”) and when the second switch SW2 is controlled to be ON (SW2ctrl=“H”) is within a range of a current H±10% when the first switch SW1 is controlled to be ON (SW1ctrl=“H”) and when the second switch SW2 is controlled to be ON (SW2ctrl=“H”) during when the first switch SW1 and the second switch SW2 are normal.

In other words, when at least any one of the above respective four determination conditions is not satisfied, at least one of the first switch SW1 and the second switch SW2 can be considered to be abnormal (failure).

Further, FIGS. 11A, 11B, 11C, and 11D show an example of numerical values when the constant voltage Vi, which is supplied from an inspection system 2, =10 V, the OFF resistance Roff of the switching element=5000Ω, and the ON resistance Ron of the switching element=1Ω.

Specifically, during when the first switch SW1 and the second switch SW2 are normal, the current E is 2 mA when the first switch SW1 is controlled to be OFF (SW1ctrl=“L”) and the second switch SW2 is controlled to be OFF (SW2ctrl=“L”).

Further, the current F is 3 mA when the first switch SW1 is controlled to be ON (SW1ctrl=“H”) and when the second switch SW2 is controlled to be OFF (SW2ctrl=“L”).

Further, the current G is 3 mA when the first switch SW1 is controlled to be OFF (SW1ctrl=“L”) and when the second switch SW2 is controlled to be ON (SW2ctrl=“H”).

Further, the current H is 4 mA when the first switch SW1 is controlled to be ON (SW1ctrl=“H”) and when the second switch SW2 is controlled to be ON (SW2ctrl=“H”).

When the failure mode of the second switch SW2 is line-open, the resistance value Rsw2 of the second switch SW2 becomes infinite regardless of the control state of the second switch SW2. At this time, the current I when the first switch SW1 is controlled to be OFF (SW1ctrl=“L”) is 1 mA, the current I when the first switch SW1 is controlled to be ON (SW1ctrl=“H”) is 2 mA, and as shown in FIG. 11A, the current I is determined to be NOT-OK regardless of the control states of the first switch SW1 and the second switch SW2.

When an open circuit failure occurs in the switching element of the second switch SW2, the resistance value Rsw2 of the second switch SW2 becomes the OFF resistance Roff in the switching element regardless of the control state of the second switch SW2. At this time, the current I when the first switch SW1 is controlled to be OFF (SW1ctrl=“L”) is 2 mA, the current I when the first switch SW1 is controlled to be ON (SWctrl=“H”) is 3 mA, and as shown in FIG. 11A, the current I when the second switch SW2 is controlled to be ON (SW2ctrl=“H”) is determined to be NOT-OK.

When a short circuit failure occurs in the switching element of the second switch SW2, the resistance value Rsw2 of the second switch SW2 becomes the ON resistance Ron in the switching element regardless of the control state of the second switch SW2. At this time, the current I when the first switch SW1 is controlled to be OFF (SW1ctrl=“L”) is 3 mA, the current I when the first switch SW1 is controlled to be ON (SW1ctrl=“H”) is 4 mA, and as shown in FIG. 11A, the current I when the second switch SW2 is controlled to be OFF (SW2ctrl=“L”) is determined to be NOT-OK.

When the failure mode of the first switch SW1 is line-open, the resistance value Rsw1 of the first switch SW1 becomes infinite regardless of the control state of the first switch SW1. At this time, the current I when the second switch SW2 is controlled to be OFF (SW2ctrl=“L”) is 1 mA, the current I when the second switch SW2 is controlled to be ON (SW2ctrl=“H”) is 2 mA, and as shown in FIG. 11B, the current I is determined to be NOT-OK regardless of the control states of the first switch SW1 and the second switch SW2.

When the failure modes of both the first switch SW1 and the second switch SW2 are line-open, the resistance values Rsw1 and Rsw2 of the first switch SW1 and the second switch SW2 become infinite regardless of the control states of the first switch SW1 and the second switch SW2. The current I at this time is substantially 0 regardless of the control states of the first switch SW1 and the second switch SW2, and as shown in FIG. 11B, the current I is determined to be NOT-OK regardless of the control states of the first switch SW1 and the second switch SW2.

When the failure mode of the first switch SW1 is line-open and an open circuit failure occurs in the switching element of the second switch SW2, the resistance value Rsw1 of the first switch SW1 becomes infinite regardless of the control state of the first switch SW1, and the resistance value Rsw2 of the second switch SW2 becomes the OFF resistance Roff in the switching element regardless of the control state of the second switch SW2. The current I at this time is 1 mA regardless of the control states of the first switch SW1 and the second switch SW2, and as shown in FIG. 11B, the current I is determined to be NOT-OK regardless of the control states of the first switch SW1 and the second switch SW2.

When the failure mode of the first switch SW1 is line-open and a short circuit failure occurs in the switching element of the second switch SW2, the resistance value Rsw1 of the first switch SW1 becomes infinite regardless of the control state of the first switch SW1, and the resistance value Rsw2 of the second switch SW2 becomes the ON resistance Ron in the switching element regardless of the control state of the second switch SW2. The current I at this time is 2 mA regardless of the control states of the first switch SW1 and the second switch SW2, and as shown in FIG. 11B, the current I is determined to be NOT-OK in a state in which the first switch SW1 is controlled to be ON (SW1ctrl=“H”) and the second switch SW2 is controlled to be OFF (SW2ctrl=“L”), and in a state in which the second switch SW2 is controlled to be ON (SW2ctrl=“H”) regardless of the control state of the first switch SW1.

When an open circuit failure occurs in the switching element of the first switch SW1, the resistance value Rsw1 of the first switch SW1 becomes the OFF resistance Roff in the switching element regardless of the control state of the first switch SW1. At this time, the current I when the second switch SW2 is controlled to be OFF (SW2ctrl=“L”) is 2 mA, the current I when the second switch SW2 is controlled to be ON (SW2ctrl=“H”) is 3 mA, and as shown in FIG. 11C, the current I in a state in which the first switch SW1 is controlled to be ON (SW1ctrl=“H”) is determined to be NOT-OK regardless of the control state of the second switch SW2.

When an open circuit failure occurs in the switching element of the first switch SW1 and the failure mode of the second switch SW2 is line-open, the resistance value Rsw1 of the first switch SW1 becomes the OFF resistance Roff in the switching element regardless of the control state of the first switch SW1, and the resistance value Rsw2 of the second switch SW2 becomes infinite regardless of the control state of the second switch SW2. The current I at this time is 1 mA regardless of the control states of the first switch SW1 and the second switch SW2, and as shown in FIG. 11C, the current I is determined to be NOT-OK regardless of the control states of the first switch SW1 and the second switch SW2.

When open circuit failures occur in the switching elements of the first switch SW1 and the second switch SW2, the resistance value Rsw1 of the first switch SW1 and the resistance value Rsw2 of the second switch SW2 become the OFF resistance Roff in the switching elements regardless of the control states of the first switch SW1 and the second switch SW2. The current I at this time is 2 mA regardless of the control states of the first switch SW1 and the second switch SW2, and as shown in FIG. 11C, the current I is determined to be NOT-OK in a state in which the first switch SW1 is controlled to be ON (SW1ctrl=“H”) and the second switch SW2 is controlled to be OFF (SW2ctrl=“L”), and in a state in which the second switch SW2 is controlled to be ON (SW2ctrl=“H”) regardless of the control state of the first switch SW1.

When an open circuit failure occurs in the switching element of the first switch SW1 and a short circuit failure occurs in the switching element of the second switch SW2, the resistance value Rsw1 of the first switch SW1 becomes the OFF resistance Roff in the switching element regardless of the control state of the first switch SW1, and the resistance value Rsw2 of the second switch SW2 becomes the ON resistance Ron in the switching element regardless of the control state of the second switch SW2. The current I at this time is 3 mA regardless of the control states of the first switch SW1 and the second switch SW2, and as shown in FIG. 11C, the current I is determined to be NOT-OK in a state in which both the first switch SW1 and the second switch SW2 are controlled to be OFF (SW1ctrl, SW2ctrl=“L”), and in a state in which both the first switch SW1 and the second switch SW2 are controlled to be ON (SW1ctrl, SW2ctrl=“H”).

When a short circuit failure occurs in the switching element of the first switch SW1, the resistance value Rsw1 of the first switch SW1 becomes the ON resistance Ron in the switching element regardless of the control state of the first switch SW1. At this time, the current I when the second switch SW2 is controlled to be OFF (SW2ctrl=“L”) is 3 mA, the current I when the second switch SW2 is controlled to be ON (SW2ctrl=“H”) is 4 mA, and as shown in FIG. 11D, the current I in a state in which the first switch SW1 is controlled to be OFF (SW1ctrl=“L”) is determined to be NOT-OK regardless of the control state of the second switch SW2.

When a short circuit failure occurs in the switching element of the first switch SW1 and the failure mode of the second switch SW2 is line-open the resistance value Rsw1 of the first switch SW1 becomes the ON resistance Ron in the switching element regardless of the control state of the first switch SW1, and the resistance value Rsw2 of the second switch SW2 becomes infinite regardless of the control state of the second switch SW2. The current I at this time is 2 mA regardless of the control states of the first switch SW1 and the second switch SW2, and as shown in FIG. 11D, the current I is determined to be NOT-OK in a state in which the first switch SW1 is controlled to be ON (SW1ctrl=“H”) and the second switch SW2 is controlled to be OFF (SW2ctrl=“L”), and in a state in which the second switch SW2 is controlled to be ON (SW2ctrl=“H”) regardless of the control state of the first switch SW1.

When a short circuit failure occurs in the switching element of the first switch SW1 and an open circuit failure occurs in the switching element of the second switch SW2, the resistance value Rsw1 of the first switch SW1 becomes the ON resistance Ron in the switching element regardless of the control state of the first switch SW1, and the resistance value Rsw2 of the second switch SW2 becomes the OFF resistance Roff in the switching element regardless of the control state of the second switch SW2. The current I at this time is 3 mA regardless of the control states of the first switch SW1 and the second switch SW2, and as shown in FIG. 11D, the current I is determined to be NOT-OK in a state in which both the first switch SW1 and the second switch SW2 are controlled to be OFF (SW1ctrl, SW2ctrl=“L”), and in a state in which both the first switch SW1 and the second switch SW2 are controlled to be ON (SW1ctrl, SW2ctrl=“H”).

When short circuit failures occur in the switching elements of the first switch SW1 and the second switch SW2, the resistance values Rsw1 and Rsw2 of the first switch SW1 and the second switch SW2 become the ON resistance Ron in the switching elements regardless of the control states of the first switch SW1 and the second switch SW2. The current I at this time is 4 mA regardless of the control states of the first switch SW1 and the second switch SW2, and as shown in FIG. 11D, the current I is determined to be NOT-OK in a state in which the second switch SW2 is controlled to be OFF (SW2ctrl=“L”) regardless of the control state of the first switch SW1, and in a state in which the first switch SW1 is controlled to be OFF (SW1ctrl=“L”) and the second switch SW2 is controlled to be ON (SW2ctrl=“H”).

As described above, in the high frequency module 1b according to Embodiment 3 having the configuration shown in FIG. 9, upper and lower limit values with respect to current values flowing through the equivalent circuit shown in FIG. 10 may be set as threshold values in each of the control states (“L”/“H” states of the control signals SW1ctrl and SW2ctrl, 22=4 ways) of the first switch SW1 and the second switch SW2 when the first switch SW1 and the second switch SW2 are normal, and a threshold value determination may be performed in each of the control states of the first switch SW1 and the second switch SW2 in the pre-shipment inspection of the high frequency module 1b.

### Embodiment 4

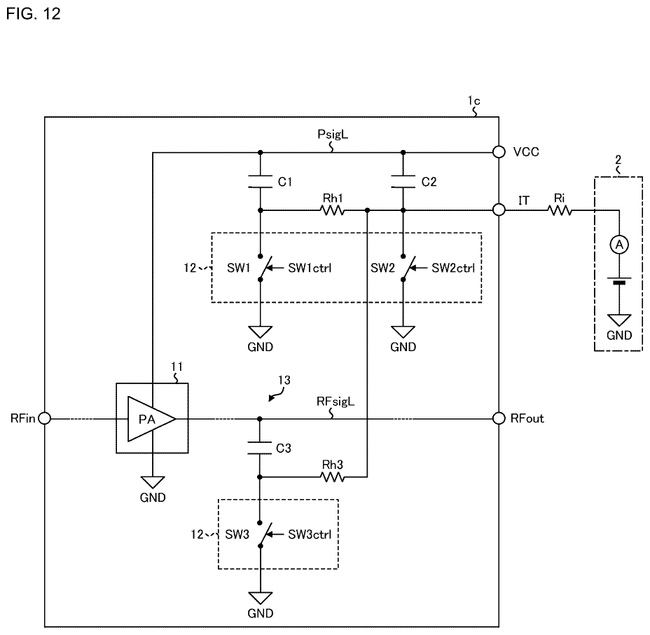

FIG. 12 is a schematic diagram showing an example of a high frequency module according to Embodiment 4. In the configuration shown in FIG. 12, in the high frequency module 1c according to Embodiment 4, a first resistor Rh1 is connected between a connection point between the first mode bypass capacitor (e.g., the first capacitor C1) and the first switch SW1 and a connection point between the second mode bypass capacitor (e.g., the second capacitor C2) and the second switch SW2, a third resistor Rh3 is connected between a connection point between the second mode bypass capacitor (e.g., the second capacitor C2) and the second switch SW2 and a connection point between the shunt capacitor (e.g., the third capacitor C3) and the third switch SW3, and an inspection terminal IT is connected to a connection point (in FIG. 12, the connection point between the second mode bypass capacitor (the second capacitor C2) and the second switch SW2) between the first resistor Rh1 and the third resistor Rh3. In addition to the configuration of the high frequency module 1c according to Embodiment 4 shown in FIG. 12, it is possible to employ a configuration including the current limit resistor Ri, similar to Embodiment 2.

The first resistor Rh1 is a high impedance resistor corresponding to the resistor Rh in Embodiment 1. Similar to the first resistor Rh1, the third resistor Rh3 is a high impedance resistor having a relatively high resistance value with respect to the current limit resistor Ri. Specifically, the resistance value of the third resistor Rh3 is, for example, set to 5000Ω.

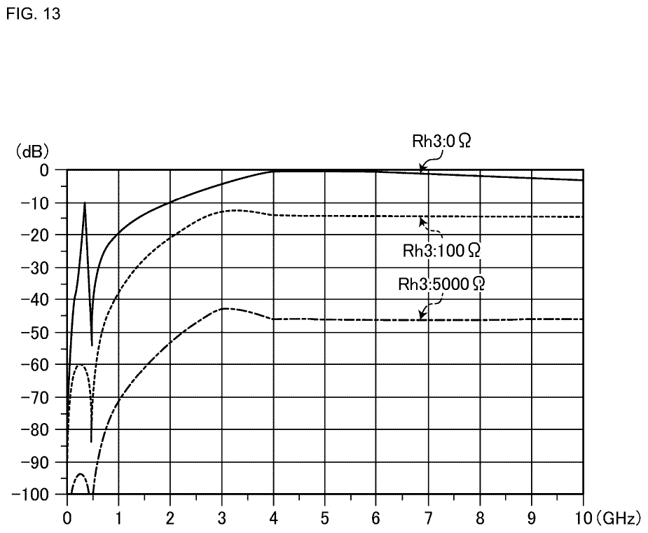

FIG. 13 is a diagram showing an example of isolation characteristics between a power source voltage supply line and a high frequency signal transmission line of the high frequency module according to Embodiment 4. FIG. 13 shows the isolation characteristics from the second signal line RFsigL, which is a high frequency signal transmission line, to the first signal line PsigL, which is a power source voltage supply line. The solid line shown in FIG. 13 indicates the isolation characteristics when the resistance value of the third resistor Rh3 is set to 0Ω. Further, the broken line shown in FIG. 13 indicates the isolation characteristics when the resistance value of the third resistor Rh3 is set to 100Ω. Further, the one-dot chain line shown in FIG. 13 indicates the isolation characteristics when the resistance value of the third resistor Rh3 is set to 5000Ω.

As indicated by the broken line in FIG. 13, sufficient isolation is not obtained when the resistance value of the third resistor Rh3 is set to 100Ω. In contrast, as indicated by the one-dot chain line in FIG. 13, sufficient isolation is ensured when the resistance value of the third resistor Rh3 is set to 5000Ω. Accordingly, deterioration in the isolation characteristics between switches can be suppressed.

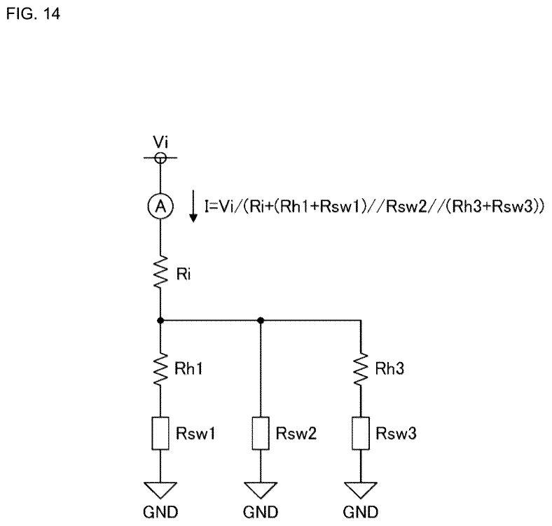

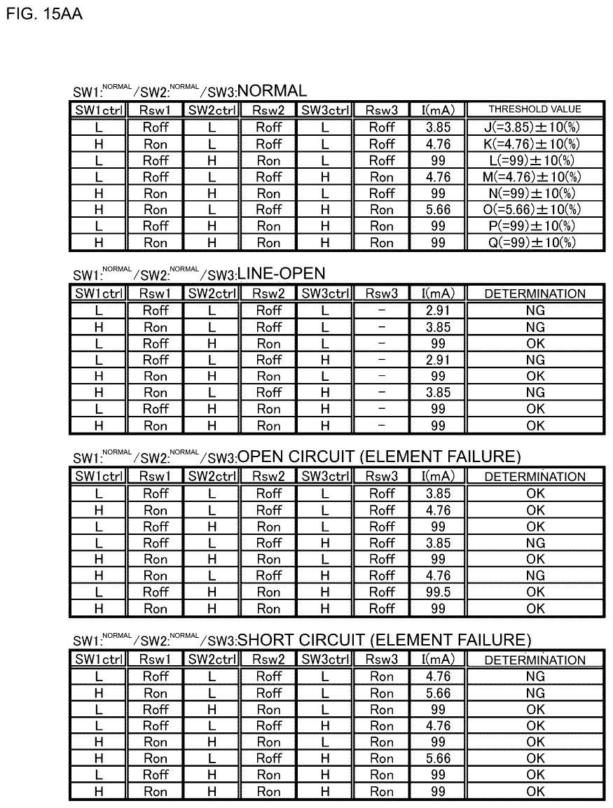

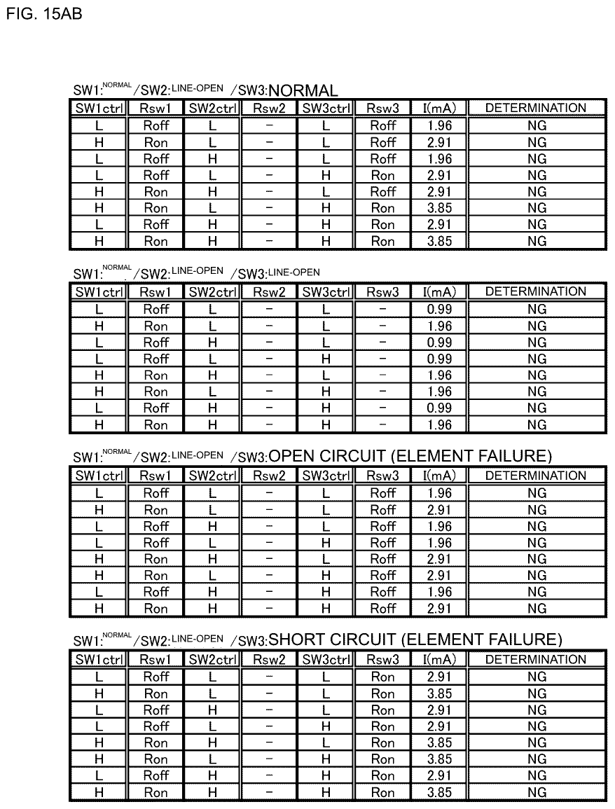

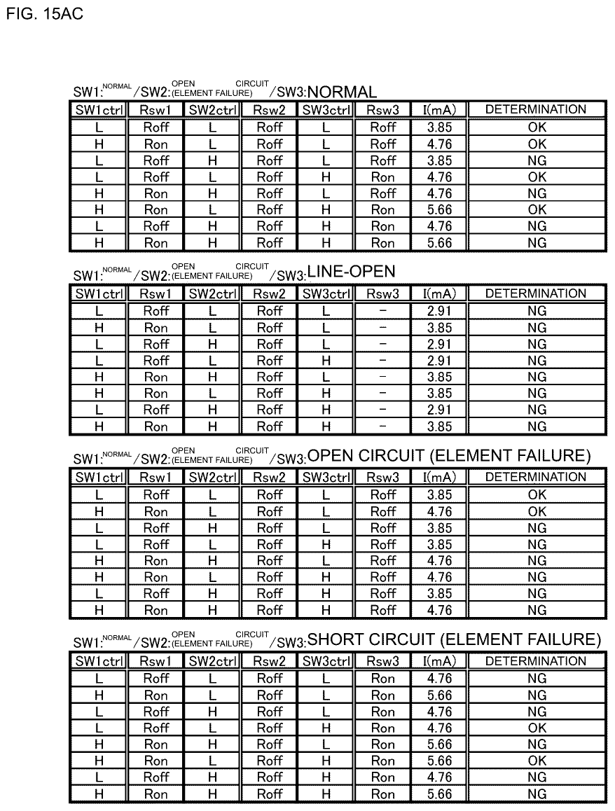

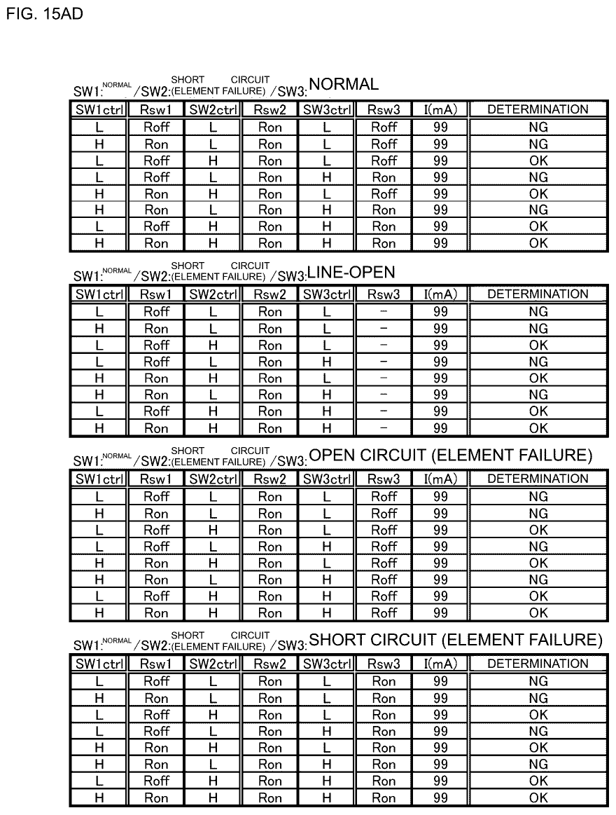

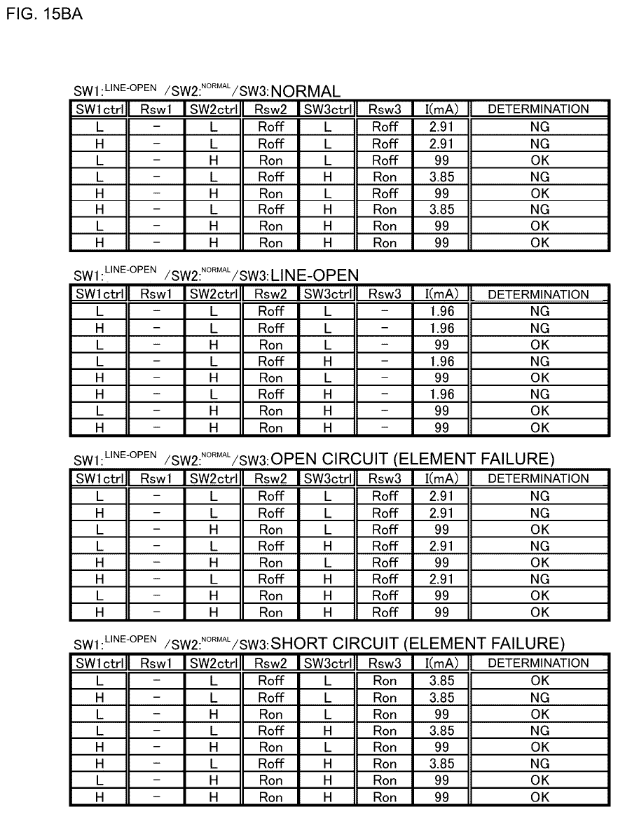

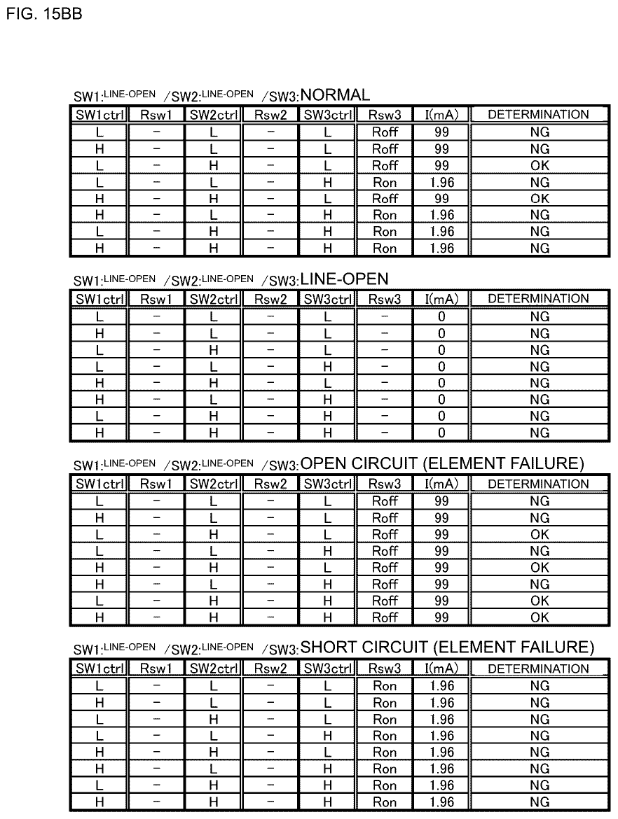

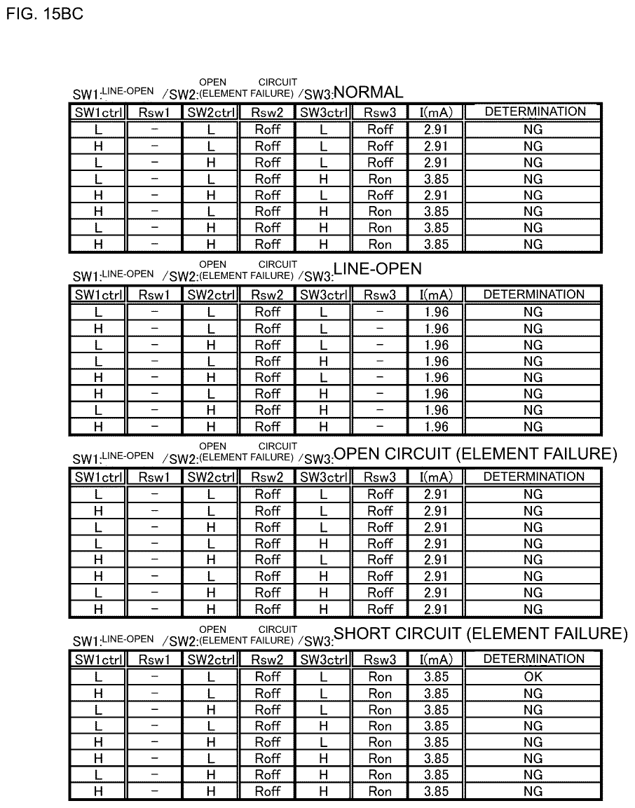

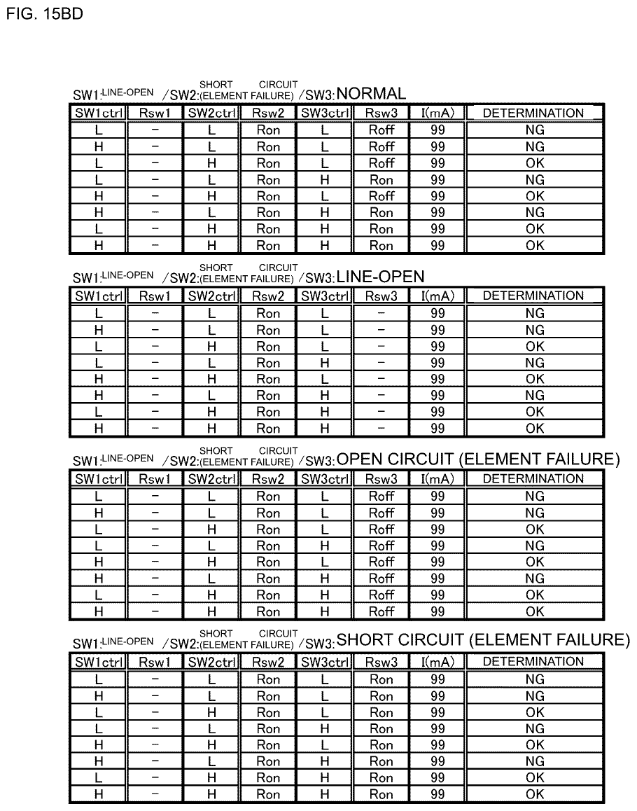

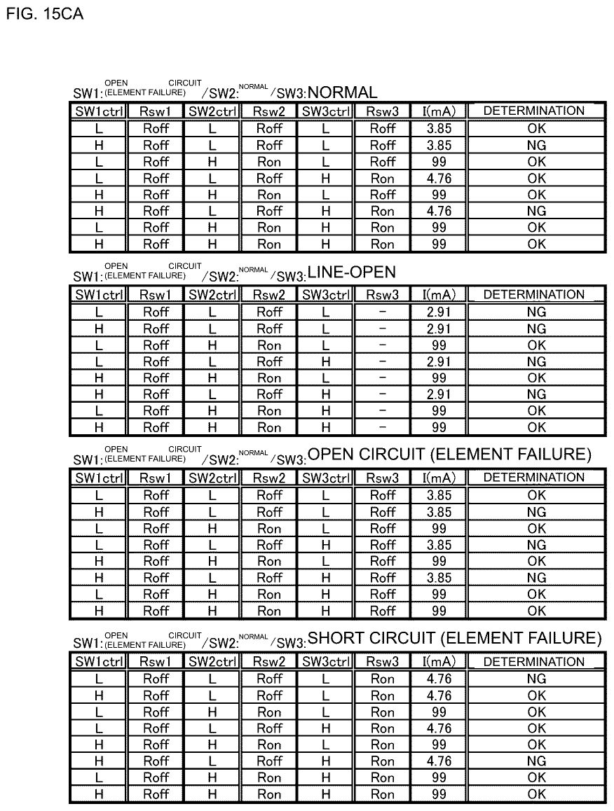

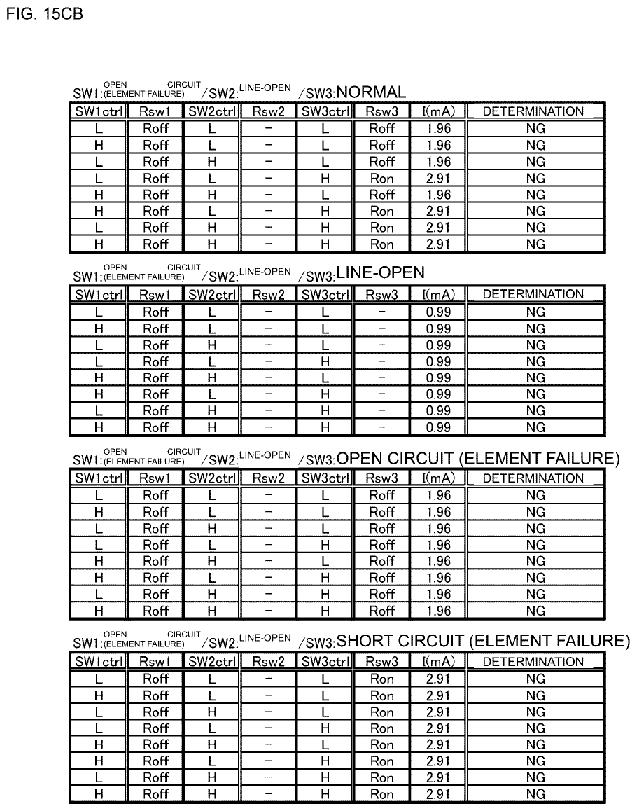

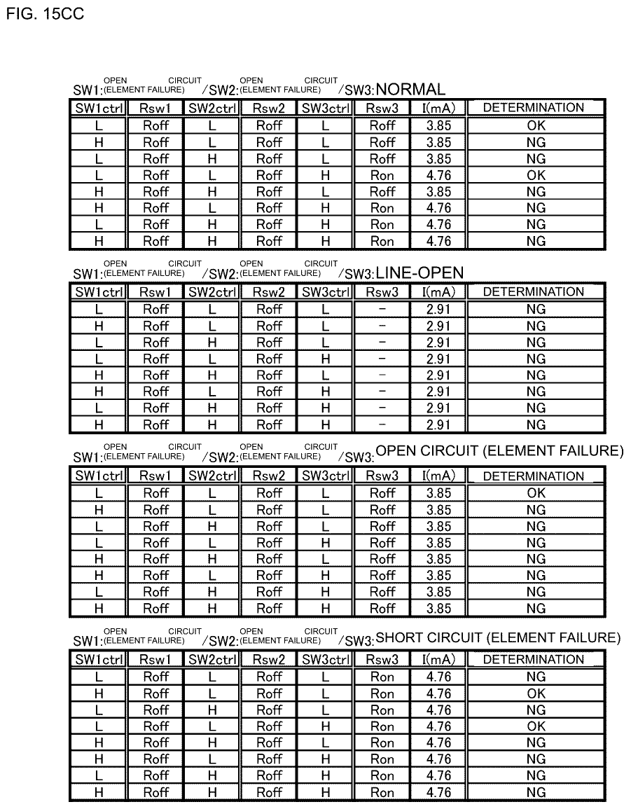

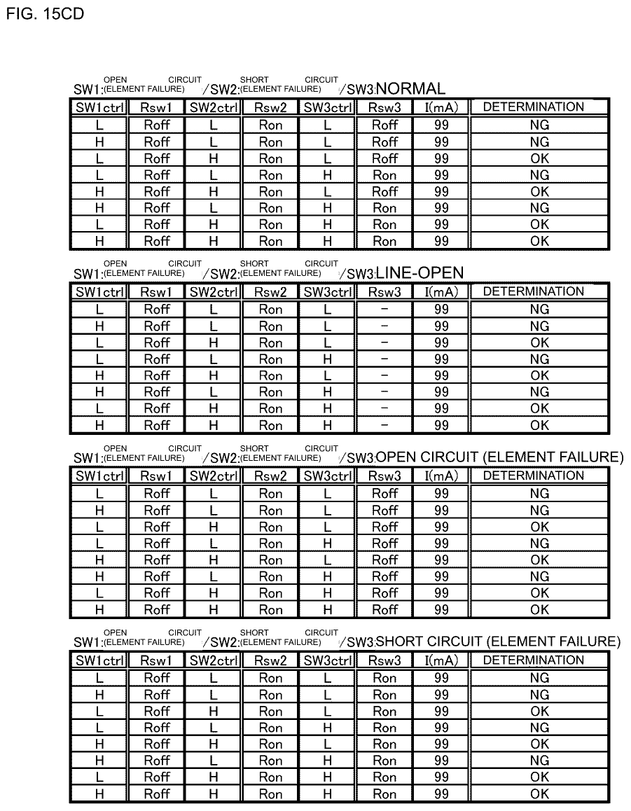

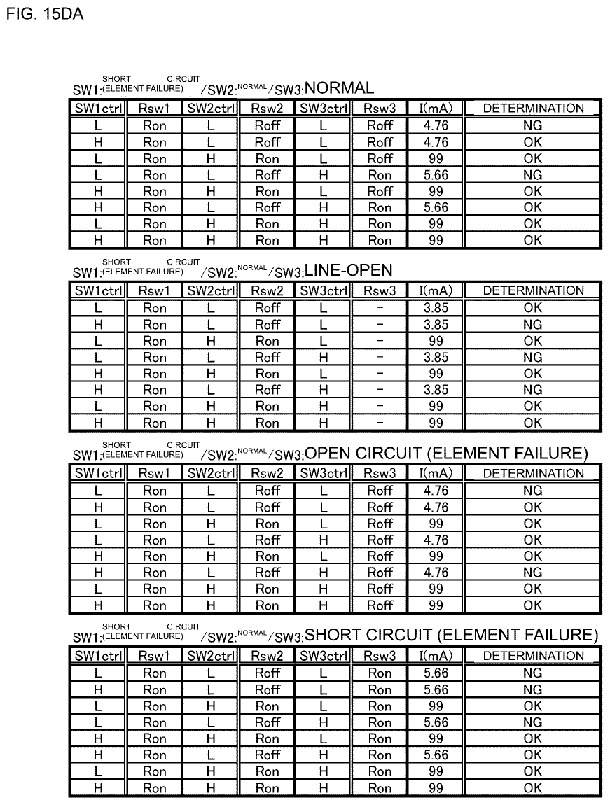

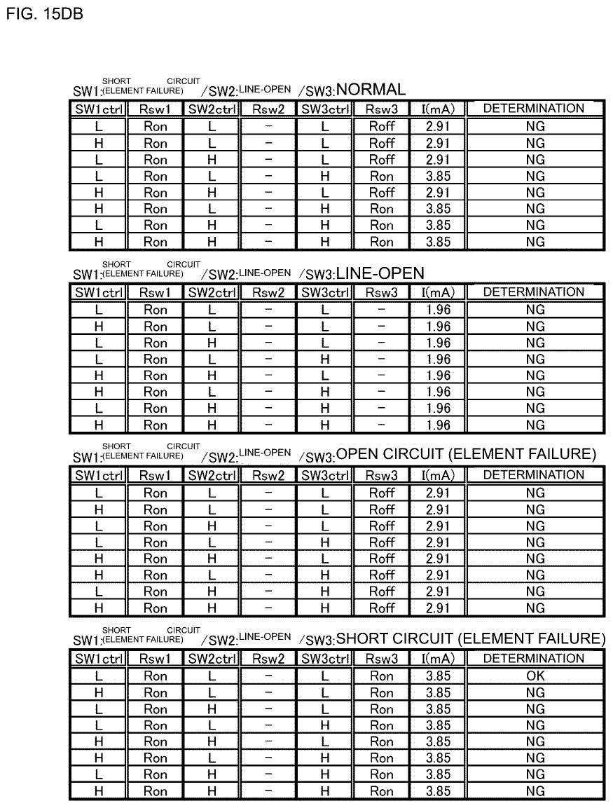

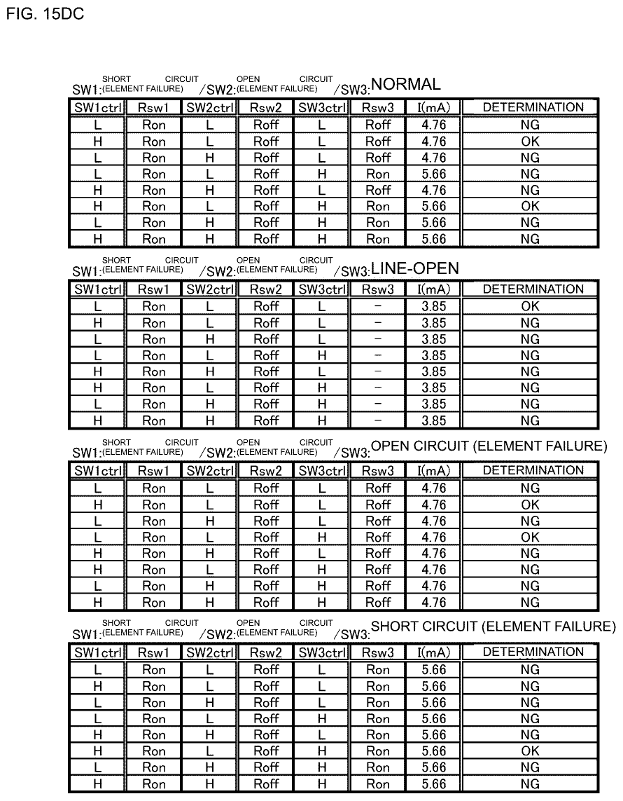

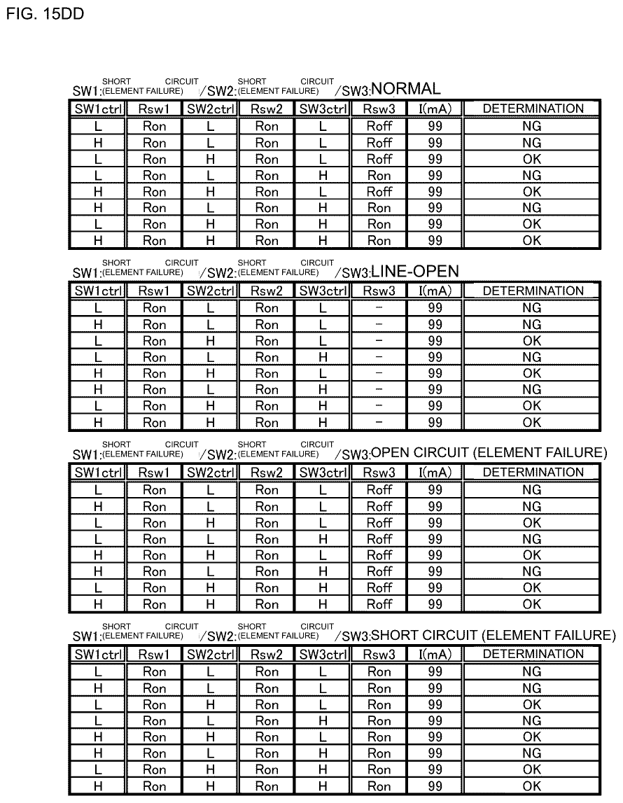

FIG. 14 is an equivalent circuit diagram of the inspection terminal in the pre-shipment inspection of the high frequency module according to Embodiment 4. FIGS. 15AA, 15AB, 15AC, 15AD, 15BA, 15BB, 15BC, 15BD, 15CA, 15CB, 15CC, 15CD, 15DA, 15DB, 15DC, and 15DD are diagrams showing an example of a switch determination in the pre-shipment inspection of the high frequency module according to Embodiment 4.

In FIG. 14, when the resistance value of the first switch SW1 is denoted by Rsw1, the resistance value of the second switch SW2 is denoted by Rsw2, and the resistance value of the third switch SW3 is denoted by Rsw3, the current I flowing through the equivalent circuit shown in FIG. 14 is expressed by the following Equation (4).

$$I = Vi / ( Ri + ( Rh 1 + Rsw 1 ) // Rsw 2 // ( Rh 3 + Rsw 3 ) ) \qquad ( 4 )$$

During when the first switch SW1, the second switch SW2, and the third switch SW3 are normal, the resistance values Rsw1, Rsw2, and Rsw3 when the first switch SW1, the second switch SW2, and the third switch SW3 are controlled to be OFF (SW1ctrl, SW2ctrl, SW3ctrl=“L”) can be represented as an OFF resistance Roff in the switching element. Further, the resistance values Rsw1, Rsw2, and Rsw3 when the first switch SW1, the second switch SW2, and the third switch SW3 are controlled to be ON (SW1ctrl, SW2ctrl, SW3ctrl=“H”) can be represented as an ON resistance Ron in the switching element. Accordingly, as shown in FIG. 15AA, when the first switch SW1, the second switch SW2, and the third switch SW3 are normal, the current I flowing through the equivalent circuit shown in FIG. 14 has different values depending on the control states of the first switch SW1, the second switch SW2, and the third switch SW3.

In the examples shown in FIGS. 15AA, 15AB, 15AC, 15AD, 15BA, 15BB, 15BC, 15BD, 15CA, 15CB, 15CC, 15CD, 15DA, 15DB, 15DC, and 15DD, when the first switch SW1, the second switch SW2, and the third switch SW3 are normal, a range of the current I±10%, which flows through the equivalent circuit shown in FIG. 14 depending on the control states of the first switch SW1, the second switch SW2, and the third switch SW3 is defined as a threshold value range in each control state.

Specifically, in the examples shown in FIGS. 15AA, 15AB, 15AC, 15AD, 15BA, 15BB, 15BC, 15BD, 15CA, 15CB, 15CC, 15CD, 15DA, 15DB, 15DC, and 15DD, an example is shown in which a determination is made that the first switch SW1, the second switch SW2, and the third switch SW3 are normal when all of the respective following determination conditions are satisfied.

### Determination Condition 1

The current I when the first switch SW1 is controlled to be OFF (SW1ctrl=“L”), when the second switch SW2 is controlled to be OFF (SW2ctrl=“L”), and when the third switch SW3 is controlled to be OFF (SW3ctrl=“L”) is within a range of a current J±10% when the first switch SW1 is controlled to be OFF (SW1ctrl=“L”), when the second switch SW2 is controlled to be OFF (SW2ctrl=“L”), and when the third switch SW3 is controlled to be OFF (SW3ctrl=“L”) during when the first switch SW1, the second switch SW2, and the third switch SW3 are normal.

### Determination Condition 2

The current I when the first switch SW1 is controlled to be ON (SW1ctrl=“H”), when the second switch SW2 is controlled to be OFF (SW2ctrl=“L”), and when the third switch SW3 is controlled to be OFF (SW3ctrl=“L”) is within a range of a current K±10% when the first switch SW1 is controlled to be ON (SW1ctrl=“H”), when the second switch SW2 is controlled to be OFF (SW2ctrl=“L”), and when the third switch SW3 is controlled to be OFF (SW3ctrl=“L”) during when the first switch SW1, the second switch SW2, and the third switch SW3 are normal.

### Determination Condition 3

The current I when the first switch SW1 is controlled to be OFF (SW1ctrl=“L”), when the second switch SW2 is controlled to be ON (SW2ctrl=“H”), and when the third switch SW3 is controlled to be OFF (SW3ctrl=“L”) is within a range of a current L±10% when the first switch SW1 is controlled to be OFF (SW1ctrl=“L”), when the second switch SW2 is controlled to be ON (SW2ctrl=“H”), and when the third switch SW3 is controlled to be OFF (SW3ctrl=“L”) during when the first switch SW1, the second switch SW2, and the third switch SW3 are normal.

### Determination Condition 4

The current I when the first switch SW1 is controlled to be OFF (SW1ctrl=“L”), when the second switch SW2 is controlled to be OFF (SW2ctrl=“L”), and when the third switch SW3 is controlled to be ON (SW3ctrl=“H”) is within a range of a current M±10% when the first switch SW1 is controlled to be OFF (SW1ctrl=“L”), when the second switch SW2 is controlled to be OFF (SW2ctrl=“L”), and when the third switch SW3 is controlled to be ON (SW3ctrl=“H”) during when the first switch SW1, the second switch SW2, and the third switch SW3 are normal.

### Determination Condition 5

The current I when the first switch SW1 is controlled to be ON (SW1ctrl=“H”), when the second switch SW2 is controlled to be ON (SW2ctrl=“H”), and when the third switch SW3 is controlled to be OFF (SW3ctrl=“L”) is within a range of a current N±10% when the first switch SW1 is controlled to be ON (SW1ctrl=“H”), when the second switch SW2 is controlled to be ON (SW2ctrl=“H”), and when the third switch SW3 is controlled to be OFF (SW3ctrl=“L”) during when the first switch SW1, the second switch SW2, and the third switch SW3 are normal.

### Determination Condition 6

The current I when the first switch SW1 is controlled to be ON (SW1ctrl=“H”), when the second switch SW2 is controlled to be OFF (SW2ctrl=“L”), and when the third switch SW3 is controlled to be ON (SW3ctrl=“H”) is within a range of a current O±10% when the first switch SW1 is controlled to be ON (SW1ctrl=“H”), when the second switch SW2 is controlled to be OFF (SW2ctrl=“L”), and when the third switch SW3 is controlled to be ON (SW3ctrl=“H”) during when the first switch SW1, the second switch SW2, and the third switch SW3 are normal.

### Determination Condition 7

The current I when the first switch SW1 is controlled to be OFF (SW1ctrl=“L”), when the second switch SW2 is controlled to be ON (SW2ctrl=“H”), and when the third switch SW3 is controlled to be ON (SW3ctrl=“H”) is within a range of a current P±10% when the first switch SW1 is controlled to be OFF (SW1ctrl=“L”), when the second switch SW2 is controlled to be ON (SW2ctrl=“H”), and when the third switch SW3 is controlled to be ON (SW3ctrl=“H”) during when the first switch SW1, the second switch SW2, and the third switch SW3 are normal.

### Determination Condition 8

The current I when the first switch SW1 is controlled to be ON (SW1ctrl=“H”), when the second switch SW2 is controlled to be ON (SW2ctrl=“H”), and when the third switch SW3 is controlled to be ON (SW3ctrl=“H”) is within a range of a current Q±10% when the first switch SW1 is controlled to be ON (SW1ctrl=“H”), when the second switch SW2 is controlled to be ON (SW2ctrl=“H”), and when the third switch SW3 is controlled to be ON (SW3ctrl=“H”) during when the first switch SW1, the second switch SW2, and the third switch SW3 are normal.

In other words, when at least any one of the above respective eight determination conditions is not satisfied, at least any one of the first switch SW1, the second switch SW2, and the third switch SW3 can be considered to be abnormal (failure).

Further, FIGS. 15AA, 15AB, 15AC, 15AD, 15BA, 15BB, 15BC, 15BD, 15CA, 15CB, 15CC, 15CD, 15DA, 15DB, 15DC, and 15DD show an example of numerical values when the constant voltage Vi, which is supplied from an inspection system 2, =10 V, the current limit resistor Ri=100Ω, the OFF resistance Roff of the switching element=5000Ω, and the ON resistance Ron of the switching element=1Ω.

Specifically, during when the first switch SW1, the second switch SW2, and the third switch SW3 are normal, the current J is 3.85 mA when the first switch SW1 is controlled to be OFF (SW1ctrl=“L”), when the second switch SW2 is controlled to be OFF (SW2ctrl=“L”), and when the third switch SW3 is controlled to be OFF (SW3ctrl=“L”).

Further, the current K is 4.76 mA when the first switch SW1 is controlled to be ON (SW1ctrl=“H”), when the second switch SW2 is controlled to be OFF (SW2ctrl=“L”), and when the third switch SW3 is controlled to be OFF (SW3ctrl=“L”).

Further, the current L is 99 mA when the first switch SW1 is controlled to be OFF (SW1ctrl=“L”), when the second switch SW2 is controlled to be ON (SW2ctrl=“H”), and when the third switch SW3 is controlled to be OFF (SW3ctrl=“L”).

Further, the current M is 4.76 mA when the first switch SW1 is controlled to be OFF (SW1ctrl=“L”), when the second switch SW2 is controlled to be OFF (SW2ctrl=“L”), and when the third switch SW3 is controlled to be ON (SW3ctrl=“H”).

Further, the current N is 99 mA when the first switch SW1 is controlled to be ON (SW1ctrl=“H”), when the second switch SW2 is controlled to be ON (SW2ctrl=“H”), and when the third switch SW3 is controlled to be OFF (SW3ctrl=“L”).

Further, the current O is 5.66 mA when the first switch SW1 is controlled to be ON (SW1ctrl=“H”), when the second switch SW2 is controlled to be OFF (SW2ctrl=“L”), and when the third switch SW3 is controlled to be ON (SW3ctrl=“H”).

Further, the current P is 99 mA when the first switch SW1 is controlled to be OFF (SW1ctrl=“L”), when the second switch SW2 is controlled to be ON (SW2ctrl=“H”), and when the third switch SW3 is controlled to be ON (SW3ctrl=“H”).

Further, the current Q is 99 mA when the first switch SW1 is controlled to be ON (SW1ctrl=“H”), when the second switch SW2 is controlled to be ON (SW2ctrl=“H”), and when the third switch SW3 is controlled to be ON (SW3ctrl=“H”).

In Embodiment 4, the description of the examples of the NOT-OK determination in the combination of the failure modes for each of the first switch SW1, the second switch SW2, and the third switch SW3 is omitted.

In the high frequency module 1c according to Embodiment 4 having the configuration shown in FIG. 12, similar to each embodiment described above, upper and lower limit values with respect to the current I flowing through the equivalent circuit shown in FIG. 14 may be set as threshold values in each of the control states (“L”/“H” states of the control signals SW1ctrl, SW2ctrl, and SW3ctrl, 23=8 ways) of the first switch SW1, the second switch SW2, and the third switch SW3 when the first switch SW1, the second switch SW2, and the third switch SW3 are normal, and a threshold value determination may be performed in each of the control states of the first switch SW1, the second switch SW2, and the third switch SW3 in the pre-shipment inspection of the high frequency module 1c.

The above-described embodiment is for easy understanding of the present disclosure and is not for limiting and interpreting the present disclosure. The present disclosure can be changed/improved without deviating from the gist of the present disclosure, and the present disclosure also includes equivalents thereof.

The present disclosure can have the following configuration as described above or instead of the above.
(1) A high frequency module according to one aspect of the present disclosure includes: a first capacitor having one end connected to a first signal line; a second capacitor having one end connected to a second signal line; a first switch that is provided between the other end of the first capacitor and a reference potential; a second switch that is provided between the other end of the second capacitor and the reference potential; an inspection terminal of the first switch and the second switch; and a resistor that is connected between a connection point between the first capacitor and the first switch and a connection point between the second capacitor and the second switch, in which the inspection terminal is electrically connected to one end of the resistor.

In this configuration, the first switch and the second switch can be inspected by using one inspection terminal without separately providing respective inspection terminals of the first switch corresponding to the first capacitor and the second switch corresponding to the second capacitor. Accordingly, it is possible to suppress the increase in the number of inspection terminals required in the pre-shipment inspection of the high frequency module.
(2) The high frequency module according to (1) further includes a current limit resistor that is connected between the one end of the resistor and the inspection terminal.

With this configuration, electromagnetic wave noise radiated from the inspection terminal to the outside of the high frequency module can be suppressed.
(3) In the high frequency module according to
(2), a resistance value of the resistor is relatively high with respect to a resistance value of the current limit resistor.

With this configuration, deterioration in the isolation characteristics between switches can be suppressed.
(4) A high frequency module according to another aspect of the present disclosure includes: a first capacitor having one end connected to a first signal line; a second capacitor having one end connected to a second signal line; a first switch that is provided between the other end of the first capacitor and a reference potential; a second switch that is provided between the other end of the second capacitor and the reference potential; an inspection terminal of the first switch and the second switch; and a first resistor and a second resistor that are connected in series between a connection point between the first capacitor and the first switch and a connection point between the second capacitor and the second switch, in which the inspection terminal is electrically connected to a connection point between the first resistor and the second resistor.

In this configuration, the first switch and the second switch can be inspected by using one inspection terminal without separately providing respective inspection terminals of the first switch corresponding to the first capacitor and the second switch corresponding to the second capacitor. Accordingly, it is possible to suppress the increase in the number of inspection terminals required in the pre-shipment inspection of the high frequency module. Further, electromagnetic wave noise radiated from the inspection terminal to the outside of the high frequency module can be suppressed.
(5) The high frequency module according to (4) further includes a current limit resistor that is connected between the connection point between the first resistor and the second resistor, and the inspection terminal.

With this configuration, electromagnetic wave noise radiated from the inspection terminal to the outside of the high frequency module can be further suppressed.
(6) In the high frequency module according to
(5), resistance values of the first resistor and the second resistor are relatively high with respect to a resistance value of the current limit resistor.

With this configuration, deterioration in the isolation characteristics between switches can be suppressed.
(7) In the high frequency module according to any one of (1) to (6), the first signal line and the second signal line are the same signal line.

With this configuration, the load capacitance of the signal line can be changed.
(8) In the high frequency module according to
(7), the signal line is a power source voltage supply line of an amplifier circuit.

With this configuration, a capacitance value suitable for a power amplification mode in the amplifier circuit can be set.
(9) In the high frequency module according to any one of (1) to (6), the first signal line is a power source voltage supply line of an amplifier circuit, and the second signal line is a high frequency signal transmission line.

In this configuration, in the pre-shipment inspection of the high frequency module, a switch for changing a capacitance value of a bypass capacitor connected to the power source voltage supply line of the amplifier circuit and a switch for changing a capacitance value of a shunt capacitor connected to the high frequency signal transmission line can be inspected with one inspection terminal.

According to the present disclosure, it is possible to realize a high frequency module that can suppress the increase in the number of inspection terminals.

Various embodiments described herein may be implemented in a computer-readable medium using, for example, software, hardware, or some combination thereof. For example, the embodiments described herein may be implemented within one or more of Application Specific Integrated Circuits (ASICs), Digital Signal Processors (DSPs), Digital Signal Processing Devices (DSPDs), Programmable Logic Devices (PLDs), Field Programmable Gate Arrays (FPGAs), processors, controllers, micro-controllers, microprocessors, other electronic units designed to perform the functions described herein, or a selective combination thereof. In some cases, such embodiments are implemented by the controller. That is, the controller is a hardware-embedded processor executing the appropriate algorithms (e.g., flowcharts) for performing the described functions and thus has sufficient structure. Also, the embodiments such as procedures and functions may be implemented together with separate software modules each of which performs at least one of functions and operations. The software codes can be implemented with a software application written in any suitable programming language. Also, the software codes can be stored in the memory and executed by the controller, thus making the controller a type of special purpose controller specifically configured to carry out the described functions and algorithms. Thus, the components shown in the drawings have sufficient structure to implement the appropriate algorithms for performing the described functions.

The present invention being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A high frequency module comprising:
a first capacitor including a first end connected to a first signal line;
a second capacitor including a first end connected to a second signal line;
a first switch provided between a second end of the first capacitor and a reference potential;
a second switch provided between a second end of the second capacitor and the reference potential;
an inspection terminal configured to allow inspection of both the first switch and the second switch; and
a resistor connected between the first capacitor and the first switch.

2. The high frequency module according to claim 1, wherein
the resistor is further connected between a connection point between the second capacitor and the second switch, and
the inspection terminal is electrically connected to a first end of the resistor.

3. The high frequency module according to claim 2, further comprising:
a current limit resistor, wherein
the current limit resistor is connected between the inspection terminal and an inspection system, or
the current limit resistor is connected between the inspection terminal and the connection point between the second capacitor and the second switch.

4. The high frequency module according to claim 3, wherein
a resistance value of the resistor is higher than a resistance value of the current limit resistor.

5. The high frequency module according to claim 1, further comprising an amplifier circuit, wherein
the first signal line is connected to the amplifier circuit, and
the first signal line is a power source voltage supply line.

6. The high frequency module according to claim 5, wherein
the first signal line is further connected to a power source terminal to supply power to the amplifier circuit, and
the amplifier circuit is configured to control the power source voltage in a first mode and a second mode.

7. The high frequency module according to claim 6, wherein
the first mode is an envelope tracking (ET) type power amplification mode that controls the power source voltage according on an amplitude level of an input signal.

8. The high frequency module according to claim 7, wherein
the second mode is an average power tracking type power amplification mode that controls the power source voltage according to an average output power.

9. The high frequency module according to claim 1, wherein
the first signal line is a power source voltage supply line of an amplifier circuit, and
the second signal line is a high frequency signal transmission line.

10. A high frequency module comprising:
a first capacitor including a first end connected to a first signal line;
a second capacitor including a first end connected to a second signal line;
a first switch provided between a second end of the first capacitor and a reference potential;
a second switch provided between a second end of the second capacitor and the reference potential;
an inspection terminal configured to allow inspection of both the first switch and the second switch;
a first resistor; and
a second resistor, wherein
the first resistor and the second resistor are connected in series between a connection point between the first capacitor and the first switch and a connection point between the second capacitor and the second switch.

11. The high frequency module according to claim 10, wherein
the inspection terminal is electrically connected to a connection point between the first resistor and the second resistor.

12. The high frequency module according to claim 10, wherein
the inspection terminal is connected between an inspection system and the connection point between the first resistor and the second resistor.

13. The high frequency module according to claim 10, further comprising:
a current limit resistor connected between the connection point between the first resistor and the second resistor, and the inspection terminal.

14. The high frequency module according to claim 13, wherein
resistance values of the first resistor and the second resistor are higher than a resistance value of the current limit resistor.

15. The high frequency module according to claim 10, further comprising an amplifier circuit, wherein
the first signal line is connected to the amplifier circuit, and
the first signal line is a power source voltage supply line.

16. The high frequency module according to claim 15, wherein
the first signal line is connected to a power source terminal to supply power to the amplifier circuit, and
the amplifier circuit is configured to control the power source voltage in a first mode and a second mode.

17. The high frequency module according to claim 16, wherein
the first mode is an envelope tracking (ET) type power amplification mode that controls the power source voltage according on an amplitude level of an input signal.

18. The high frequency module according to claim 17, wherein
the second mode is an average power tracking type power amplification mode that controls the power source voltage according to an average output power.

19. The high frequency module according to claim 10, wherein
the first signal line is a power source voltage supply line of an amplifier circuit.

20. The high frequency module according to claim 19, wherein the second signal line is a high frequency signal transmission line.
